(19) United States
(12) Patent Application Publication
(10) Pub. No.: US 2006/0267022 A1
(43) Pub. Date: Nov. 30, 2006

(54) Field-effect transistor and thyristor

(75) Inventors: Makoto Mizukami, Kawasaki-Shi (JP); Takashi Shinohe, Yokosuka-Shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/369,766

(22) Filed: Mar. 8, 2006

(30) Foreign Application Priority Data
May 31, 2005 (JP) 2005-160152
Jan. 13, 2006 (JP) 2006-006396

(51) Int. Cl. H01L 31/0312

(52) U.S. Cl. 257/77

(57) ABSTRACT

A decrease in breakdown voltage can be prevented as much as possible. A field-effect transistor includes: a drain region made of SiC; a drift layer which is formed on the drain region and is made of n-type SiC; a source region which is formed on the surface of the drift layer and is made of n-type SiC; a channel region which is formed on the surface of the drift layer located on a side of the source region and is made of SiC; an insulating gate which is formed on the channel region; and a p-type base region interposed between the bottom portion of the source region and the drift region, and containing two kinds of p-type impurities.

### CROSS-REFERENCE TO RELATED APPLICATION

This application is based upon and claims the benefit of priority from prior Japanese Patent Application Nos. 2005-160152 and 2006-6396, filed on May 31, 2005 and Jan. 13, 2006 in Japan, the entire contents of which are incorporated herein by reference.

### BACKGROUND OF THE INVENTION

1. Field of the Invention

The present invention relates to a field-effect transistor and a thyristor.

2. Related Art

SiC insulated gate transistors that have SiC semiconductor layers with wider band gaps and higher breakdown field intensity than silicon have been known (see Japanese Patent Laid-open Publication No. 2000-286415, for example).

Each of such SiC insulated gate transistors has a high-concentration base region with p-type conductivity that is selectively formed through island-like ion implantation in the surface of a low-concentration n-type epitaxial layer. A bias is applied to an insulating gate formed on the surface of an end portion of the base region, so that the portion of the p-type base region in the vicinity of the insulating gate is reversed, and a channel region for n-type carriers to move through is formed. Also, in a case of a vertical device, a low-concentration n-type epitaxial layer (a drift layer) interposed between a p-type base region connected to a source electrode and a drain region connected to a high-concentration n-type region is depleted so as to maintain a desired breakdown voltage in the device.

In a case where the p-type base region is formed through aluminum ion implantation, aluminum thermal diffusion is hardly caused in SiC, and accordingly, the bottom portion of the ion implanting region virtually remains in the same position after the heating process (an activation anneal). As a result, crystalline defects caused at the bottom portion of the implanting region during the ion implanting process remains at the bottom portion (the interface between the p-type base region and the epitaxial layer) of the ion implanting region even after the heating process. Intense field concentration is then caused on the crystalline defects when the transistor is turned off, and a decrease is caused in breakdown voltage.

In a case where the p-type base region is formed with boron, boron thermal diffusion is caused in SiC. Therefore, a heating process is carried out after ion implantation. As a result, boron thermal diffusion reaches a deeper position than the bottom surface of the ion implanting region, and the diffused boron covers the crystalline defective region formed by the ion implantation. Thus, electric field concentration due to the defects can be restrained at the n-type epitaxial layer interface.

However, the boron energy level is deeper than the aluminum energy level. When a large voltage variation (dV/dt) is applied to the transistor, the boron in the p-type base region cannot cope with the variation and temporarily stops functioning as a p-type base region. As a result, the depletion layer in the p-type base region becomes too long, and causes so-called punchthrough (dynamic punchthrough). With that, the breakdown voltage deteriorates.

To counter this problem, it is necessary to develop a structure that does not have ion-implantation crystalline defects remaining at the interface between the p-type base region and the epitaxial layer, and has such a p-type base region as not to cause dynamic punchthrough.

Moreover, boron has a higher resistance than aluminum. In the case where the p-type base region is formed only with boron, when carrier (electron) charge and discharge in the depletion layer of the n-type drift layer and hole charge and discharge in the p-type base region are caused as the transistor is turned on and off, holes cannot move fast enough due to the internal resistance in the region extending from the portion of the p-type contact region connected to the source electrode to the channel region below the insulating gate. As a result, the potential varies, and stabilizing operations become difficult.

Also, there have been trench MOSFETs each having a trench gate and an insulating film on the trench surface, and those trench MOSFETs include trench IGBTs each having a drain region with a different conductivity type from the conductivity of the source region. In a case where the semiconductor layer is made of SiC, an extremely high electric field is applied to the insulating film under the SiC operating conditions, and insulation breakdown is caused, because the breakdown intensity of SiC is similar to that of the insulating film. So as to alleviate the electric field in the insulating film, a p-type field alleviating layer is provided at the bottom portion of the insulating film. If aluminum (Al) is employed as p-type impurities to form the p-type field alleviating layer, electric field concentration is caused on crystalline defects formed by the ion implantation, and the breakdown voltage decreases. If boron (B) is employed, the electric field is applied directly to the insulating film due to dynamic punchthrough, resulting in insulation breakdown.

Furthermore, the high-concentration p-type base region formed through ion implantation has crystalline defects caused in the base and on the surface during the ion implanting process. The surface of the ion implanting region is deformed, and carriers are scattered in the channel region. As a result, the mobility of the carriers becomes extremely low (approximately a few cm²/(V·s) to ten and a few cm²/(V·s)). The decrease in mobility leads to an increase in channel resistance, and therefore, formation of a channel region with less surface deformation is expected.

Also, as the gate length becomes shorter, a larger yield decrease is caused due to the misalignment between the source region and the n-type region.

### SUMMARY OF THE INVENTION

An object of the present invention is to provide a field-effect transistor and a thyristor that can most effectively prevent a decrease in breakdown voltage.

A field-effect transistor according to a first aspect of the present invention includes: a drain region made of SiC; a drift layer which is formed on the drain region and is made of n-type SiC; a source region which is formed on a surface of the drift layer and is made of n-type SiC; a channel region which is formed on a surface of the drift layer located on a side of the source region and is made of SiC; an insulating gate formed on the channel region; and a p-type base region interposed between a bottom portion of the source region and the drift layer, and containing two kinds of p-type impurities.

A field-effect transistor according to a second aspect of the present invention includes: a drain region made of SiC; a drift layer which is formed on the drain region and is made of n-type SiC; a channel region which is formed on the drift layer and is made of SiC; a gate region which is formed on the channel region and is made of p-type SiC; a gate electrode connected to the gate region; a source region being adjacent to the channel region; and a p-type base region interposed between a bottom portion of the source region and the drift region, and containing two kinds of p-type impurities.

The gate region can be made of SiC containing two kinds of p-type impurities; the two kinds of p-type impurities can be boron and aluminum; and a lower plane of the region containing boron of the gate region can be located at the same position as or at a deeper position than a lower plane of the region containing aluminum of the gate region.

The field-effect transistor can further comprise a p-type contact region which is to be electrically connected to the base region and is formed in the source region.

The two kinds of p-type impurities in the base region can be boron and aluminum; and a lower plane of the region containing boron of the p-type base region can be located at the same position as or at a deeper position than a lower plane of the region containing aluminum of the p-type base region.

At least one of a side portion and an upper portion of the region containing boron of the p-type base region or the gate region can have a region with a higher carbon concentration than the region containing boron.

A source electrode connecting to the source region can be formed on the source region; the lower surface of the source electrode can have a smaller area than the film area of the region containing aluminum of the p-type base region; and when the p-type base region is seen from the source electrode, the source electrode can be located within the region containing aluminum of the p-type base region.

The channel region can be of a p-type.

The channel region can be of an n-type.

The channel region can be an epitaxial layer.

The field-effect transistor can further comprise a p-type layer which is provided between the channel region and the p-type base region, and contains boron.

The field-effect transistor can further comprise a region containing boron an opposite side of the region containing aluminum from the gate electrode.

The drain region can be of an n-type.

The drain region can be of a p-type.

A thyristor according to a third aspect of the present invention includes: a cathode electrode; an n-type layer which is made of SiC and is formed on the cathode electrode; a first layer which is made of SiC, is formed on the n-type layer, and contains aluminum; a second layer which is made of SiC, is formed on the first layer containing aluminum, and contains boron; an n-type drift layer which is made of SiC and is formed on the second layer containing boron; a p-type region which includes a third layer that is formed on the n-type drift layer and contains boron, and a fourth layer that is formed on the third layer containing boron and contains aluminum; an anode electrode formed on the p-type region, the anode electrode having a lower face which has a smaller area than the film area of the first and fourth layers containing aluminum, and being located within the first and fourth layers containing aluminum, when the first and fourth layers containing aluminum are seen from the anode electrode; an n-type region which is formed on the n-type drift layer; and a gate electrode which is connected to the n-type region.

### BRIEF DESCRIPTION OF THE DRAWINGS

FIGS. 1A through 1C are cross-sectional views illustrating the steps for manufacturing a SiC insulated gate transistor according to a first embodiment of the present invention;

FIGS. 2A through 2B are cross-sectional views illustrating the steps for manufacturing a SiC insulated gate transistor according to the first embodiment of the present invention;

FIGS. 3A through 3C are cross-sectional views illustrating the steps for manufacturing a SiC insulated gate transistor according to the first embodiment of the present invention;

FIGS. 4A through 4C are cross-sectional views illustrating the steps for manufacturing a SiC insulated gate transistor according to the first embodiment of the present invention;

FIGS. 5A through 5C are cross-sectional views illustrating the steps for manufacturing a SiC insulated gate transistor according to the first embodiment of the present invention;

FIG. 6 is a cross-sectional view illustrating the step for manufacturing a SiC insulated gate transistor according to the first embodiment of the present invention;

FIG. 7 is a cross-sectional view illustrating the step for manufacturing a SiC insulated gate transistor according to the first embodiment of the present invention;

FIGS. 8A through 8D illustrate the effects of the first embodiment;

FIG. 9 is a cross-sectional view of a SiC insulated gate transistor according to a second embodiment of the present invention;

FIG. 10 is a cross-sectional view of a SiC insulated gate transistor according to a third embodiment of the present invention;

FIG. 11 is a cross-sectional view illustrating the step for manufacturing a SiC insulated gate transistor according to the third embodiment of the present invention;

FIG. 12 is a cross-sectional view illustrating the step for manufacturing a SiC insulated gate transistor according to the third embodiment of the present invention;

FIG. 13 is a cross-sectional view illustrating the step for manufacturing a SiC insulated gate transistor according to the third embodiment of the present invention;

FIG. 14 is a cross-sectional view illustrating the step for manufacturing a SiC insulated gate transistor according to the third embodiment of the present invention;

FIG. 15 is a cross-sectional view illustrating the step for manufacturing a SiC insulated gate transistor according to the third embodiment of the present invention;

FIG. 16 is a cross-sectional view illustrating the step for manufacturing a SiC insulated gate transistor according to the third embodiment of the present invention;

FIG. 17 is a cross-sectional view of a SiC insulated gate transistor according to a modification of the third embodiment of the present invention;

FIG. 18 is a cross-sectional view of a SiC insulated gate transistor according to a fourth embodiment of the present invention;

FIG. 19 is a cross-sectional view of a SiC insulated gate transistor according to a fifth embodiment of the present invention;

FIG. 20 is a cross-sectional view illustrating the step for manufacturing a SiC insulated gate transistor according to the fifth embodiment of the present invention;

FIG. 21 is a cross-sectional view of a SiC insulated gate transistor according to a modification of the fifth embodiment of the present invention;

FIG. 22 is a cross-sectional view of a SiC insulated gate transistor according to a sixth embodiment of the present invention;

FIG. 23 is a cross-sectional view of a SiC insulated gate transistor according to a seventh embodiment of the present invention;

FIG. 24 is a cross-sectional view of a SiC insulated gate transistor according to a modification of the seventh embodiment of the present invention;

FIG. 25 is a cross-sectional view of a SiC insulated gate transistor according to an eighth embodiment of the present invention;

FIG. 26 is a cross-sectional view of a SiC insulated gate transistor according to a ninth embodiment of the present invention;

FIG. 27 is a cross-sectional view illustrating the step for manufacturing a SiC insulated gate transistor according to the ninth embodiment of the present invention;

FIG. 28 is a cross-sectional view of a SiC insulated gate transistor according to a modification of the ninth embodiment of the present invention;

FIG. 29 is a cross-sectional view of a SiC insulated gate transistor according to a tenth embodiment of the present invention;

FIG. 30 is a cross-sectional view of a SiC insulated gate transistor according to an eleventh embodiment of the present invention;

FIG. 31 is a cross-sectional view of a SiC insulated gate transistor according to a modification of the eleventh embodiment of the present invention;

FIG. 32 is a cross-sectional view of a SiC insulated gate transistor according to a twelfth embodiment of the present invention;

FIG. 33 is a cross-sectional view of a SiC insulated gate transistor according to a thirteenth embodiment of the present invention;

FIG. 34 is a cross-sectional view of a SiC insulated gate transistor according to a fourteenth embodiment of the present invention;

FIG. 35 is a cross-sectional view of a SiC junction field-effect transistor according to a fifteenth embodiment of the present invention;

FIG. 36 is a cross-sectional view of a SiC junction field-effect transistor according to a modification of the fifteenth embodiment;

FIG. 37 is a cross-sectional view of a SiC static induction thyristor according to a sixteenth embodiment of the present invention;

FIG. 38 is a cross-sectional view of a SiC static induction thyristor according to a modification of the sixteenth embodiment of the present invention;

FIG. 39 is a cross-sectional view of a SiC junction field-effect transistor according to a seventeenth embodiment of the present invention;

FIG. 40 is a cross-sectional view of a SiC junction field-effect transistor according to a modification of the seventeenth embodiment;

FIG. 41 is a cross-sectional view of a SiC static induction thyristor according to an eighteenth embodiment of the present invention;

FIG. 42 is a cross-sectional view of a SiC static induction thyristor according to a modification of the eighteenth embodiment of the present invention;

FIG. 43 is a cross-sectional view of a SiC static induction thyristor according to a nineteenth embodiment of the present invention;

FIG. 44 is a cross-sectional view of a SiC static induction thyristor according to a modification of the nineteenth embodiment of the present invention;

FIGS. 45A and 45B illustrate a first example of a method of forming a boron region through ion implantation according to a twentieth embodiment of the present invention; and

FIGS. 46A and 46B illustrate a second example of a method of forming a boron region through ion implantation according to the twentieth embodiment of the present invention.

### DETAILED DESCRIPTION OF THE INVENTION

The following is a detailed description of embodiments of the present invention, with reference to the accompanying drawings.

### First Embodiment

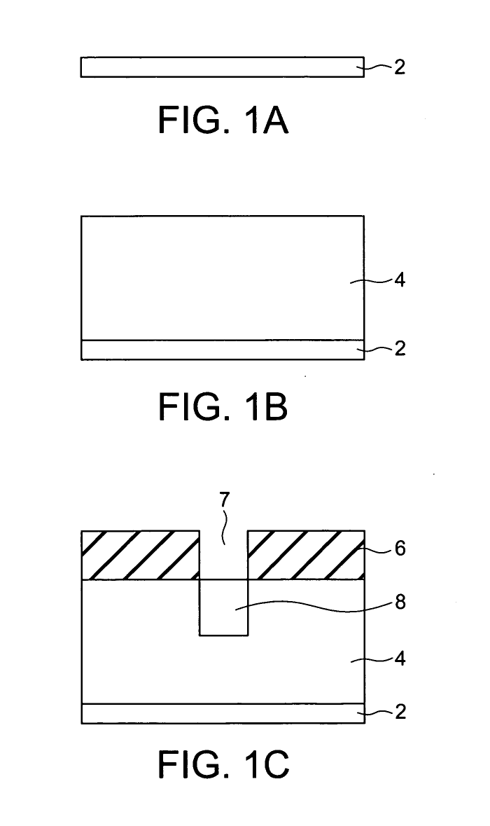

Referring to FIGS. 1A through 8D, a SiC insulated gate transistor (a field-effect transistor) according to a first embodiment of the present invention is described. The SiC insulated gate transistor of this embodiment includes a SiC semiconductor layer that has a p-type base region forming a main junction with an n-type drift layer and containing aluminum and boron elements. In this insulated gate transistor, at least the bottom surface of the aluminum region containing mostly aluminum is covered with a region that contains boron. In other words, the aluminum concentration profile in the depth direction is designed to be equal to or shallower than the boron profile in the depth direction.

The structure of the SiC insulated gate transistor of this embodiment is now described, with reference to FIGS. 1A through 7 illustrating the manufacturing procedures. As shown in FIG. 1A, a SiC substrate 2 with a low resistance is prepared, and a 10-μm n-type epitaxial layer 4 that is to be a drift region and has an impurity concentration of 1×10¹⁶ cm⁻³ is formed on the SiC substrate 2 (see FIG. 1B). The substrate concentration and thickness depend on the target design. For example, where a unipolar device of 4H—SiC (0001) is to be produced, the relationship between the target breakdown voltage V [V] and the optimum concentration N (cm⁻³) of the drift layer is expressed as N=1.70×10²⁰×V^{-1.303}, while the relationship between the target breakdown voltage V and the optimum thickness W (cm) of the drift layer is expressed as W=1.94×10⁻⁷×V^{1.1517}. Likewise, where a unipolar device of 4H—SiC (11-20) is to be produced, the relationship between the target breakdown voltage and the optimum concentration N of the drift layer is expressed as N=8.00×10¹⁹×V^{-1.303}, while the relationship between the target breakdown voltage and the optimum thickness of the drift layer is expressed as W=2.82×10⁻⁷×V^{1.1517}. Also, where a unipolar device of 6H—SiC (0001) is to be produced, the relationship between the target breakdown voltage V and the optimum concentration N of the drift layer is expressed as 2.62×10²⁰×V^{-1.323}, while the relationship between the target breakdown voltage V and the optimum thickness W of the drift layer is expressed as 1.57×10⁻⁷×V^{1.1617}. Here, 4H and 6H each represent the polymorphism of SiC single crystals. More specifically, 4H represents 4-cycle hexagonal crystals, and 6H represents 6-cycle hexagonal crystals. Meanwhile, (0001) and (11-20) each represent an orientation of crystals (see “Fundamentals and Application of SiC Device”, First Edition, edited by Kazuo Arai and Sadafumi Yoshida, Ohmsha, 2003). For example, where the target breakdown voltage is 1200 V, the thickness is 6.8 μm, and the concentration is 1.7×10¹⁶ (cm⁻³).

The “drift layer thickness” indicates the distance between the bottom of the epitaxial layer formed on the surface of the low-resistance substrate and the main junction, and in this specification, it indicates the distance between the bottom of the epitaxial layer and the p-type base region interface. Therefore, if a gate impurity region or a source impurity region exists above the main junction, the total thickness of the drift layer and the upper impurity region is equal to the epitaxial layer thickness.

Furthermore, so as to improve the yield of the devices to achieve the target breakdown voltage, the forward characteristics, and the dynamic characteristics, the drift layer thickness is optimized in the range of ±50% (more preferably, ±20%) of the optimum drift layer thickness, and the drift layer concentration is optimized in the range of ±50% (more preferably, ±20%) of the optimum drift layer concentration.

The SiC substrate 2 serves as a drain. Organic contamination remaining on the substrate 2 on which the epitaxial layer 4 formed are removed with a mixed acid of sulfuric acid and hydrogen peroxide solution, and the epitaxial layer 4 and the substrate 2 are rinsed with pure water. Metal impurities remaining on the substrate 2 and the epitaxial layer 4 are then removed with a mixed acid of dilute hydrochloric acid and hydrogen peroxide solution, and the epitaxial layer 4 and the substrate 2 are rinsed with pure water. Lastly, a native oxide film on the surfaces of the substrate 2 and the epitaxial layer 4 is removed with dilute hydrofluoric acid, and the epitaxial layer 4 and the substrate 2 are rinsed with pure water. The substrate 2 and the epitaxial layer 4 are then heated in an oxygen atmosphere at 900° C. to 1200° C. for 5 minutes to 4 hours, so as to oxidize the surface of the epitaxial layer 4 to form a sacrifice oxide film (not shown). In this embodiment, the heating is performed at 1100° C. for two hours. This sacrifice oxide film is formed to increase the adhesiveness with an oxide film to serve as an ion implanting mask formed in a later step. This sacrifice oxide film also prevents metal contamination on the surface of the substrate 2 using a metal mask in the next step.

Next, a metal layer (not shown) to serve as an ion implanting mask is formed on the upper face of the epitaxial layer 4, with the sacrifice oxide film existing between the metal layer and the epitaxial layer 4. Resist (not shown) is applied onto the metal layer, and is patterned by a photolithography technique. Thus, a resist pattern that has openings at the locations corresponding to a reserved region and a guard ring region to serve as a termination structure is formed. With this resist pattern serving as a mask, the metal layer is patterned to form an ion implanting mask. Using this ion implanting mask, multi-stage implantation of aluminum ions is carried out with a total dose amount of 1.0×10¹² cm⁻² to 1.0×10¹⁵ cm⁻² and a maximum acceleration energy of 50 keV to 500 keV, so as to form the reserved region and the guard ring region. In this embodiment, the reserved region and the guard ring region are formed with a total dose amount of 1.5×10¹³ cm⁻² and a maximum acceleration energy of 300 keV. Organic matters such as the resist and the ion implanting mask remaining on the surface of the substrate 2 are removed with a mixed acid of sulfuric acid and hydrogen peroxide solution, and the surface of the substrate 2 is rinsed with pure water.

Next, an oxide film of 2 μm in thickness to be an ion implanting mask is formed on the sacrifice oxide film by reactive sputtering or CVD (Chemical Vapor Deposition). Resist is then applied onto the oxide film and is patterned so as to form a resist pattern. With this resist pattern serving as a mask, the oxide film is patterned to form an oxide film mask 6 by RIE (Reactive Ion Etching). This oxide film mask 6 has an opening 7 above a p-type contact region 8 of the epitaxial layer 4 (see FIG. 1C). Using this oxide film mask 6, multi-stage implantation of Al ions is carried out on the surface of the epitaxial layer 4 with a maximum acceleration energy of 100 keV to 500 keV, more specifically, 300 keV, for example, so as to form the p-type contact region 8 (see FIG. 1C). This p-type contact region 8 is designed to have a box profile with a depth of approximately 0.5 μm and an Al concentration of 1×10¹⁸ cm⁻² to 1×10²¹ cm⁻³, more specifically, 1×10²⁰ cm⁻³, for example.

Next, multi-stage implantation of P (phosphorus) ions is carried out onto the bottom surface of the substrate 2 with a total dose amount of 5×10¹³ cm⁻² to 1×10¹⁷ cm⁻², more specifically, 7×10¹⁵ cm⁻², for example, and a maximum acceleration energy of 200 keV, so as to form an ohmic contact region (not shown) for a bottom-surface electrode.

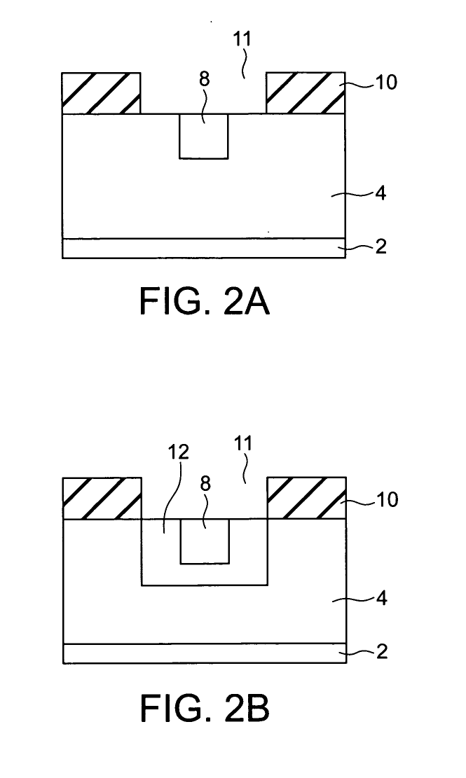

After the oxide film mask 6 and the sacrifice oxide film are peeled off with dilute hydrofluoric acid, an oxide film mask 10 of 2 μm in thickness having an opening 11 above a p-type base region to be formed in the next step is formed (see FIG. 2A). This oxide film mask 10 may be the oxide film mask 6 that is not removed and has the opening 7 widened to be the opening 11.

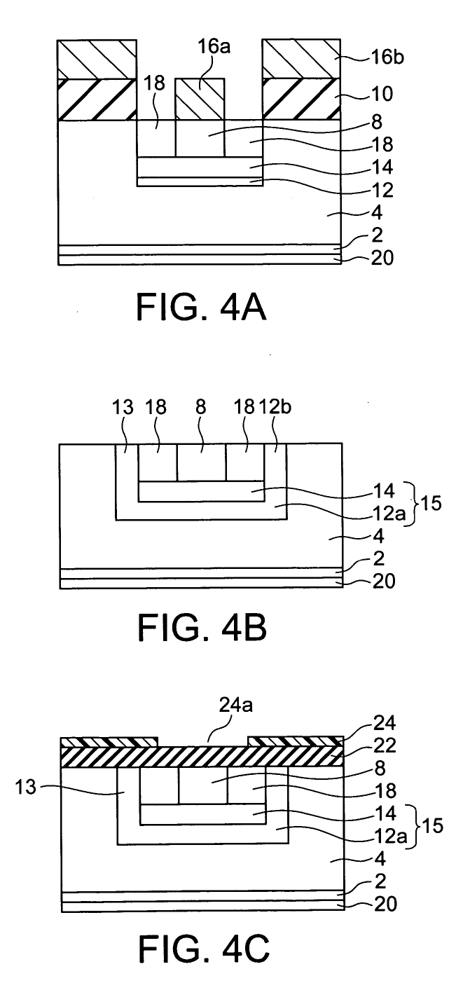

Next, using the oxide film mask 10, multi-stage implantation of boron ions is carried out so as to form a boron implanting region 12 (see FIG. 2B). This boron implanting region 12 is designed to have a box profile having a depth of up to approximately 1 μm, with an ion implantation concentration of 1×10¹⁶ cm⁻³ to 1×10²⁰ cm⁻³, more specifically, 1×10¹⁸ cm⁻³, for example, and a maximum acceleration energy of 200 keV to 800 keV, more specifically, 400 keV, for example. The boron implanting region 12 may have a box profile with a depth up to approximately 1 μm from the substrate surface. However, the boron is thermally diffused through an activation anneal in a later step. Therefore, it is not necessary to implant ions in the region of 0.3 μm to 0.5 μm from the substrate surface. Since the region of 0.3 μm to 0.5 μm from the substrate surface in which boron ions are not to be implanted is formed, a high-concentration n-type source region can be formed on the substrate surface at the time of n-type source region formation in a later step (see FIG. 4A). Accordingly, the ON resistance can be lowered. With the thermal diffusion of boron being taken into consideration, the boron region should become deeper than the aluminum implanting region after the diffusion, and the maximum acceleration energy for the boron ion implantation may be approximately 320 keV.

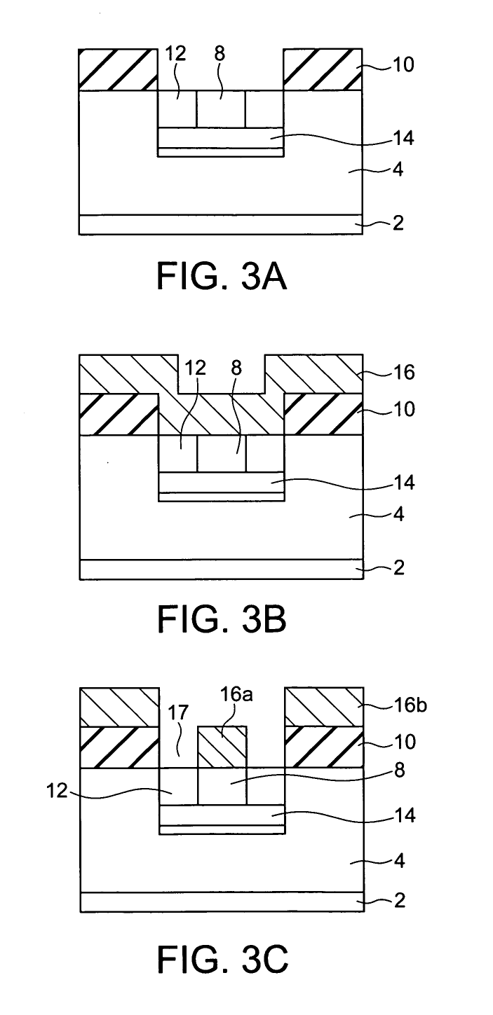

Next, using the oxide film mask 10, multi-stage implantation of aluminum ions is carried out so as to form a high-concentration aluminum implanting region 14 at the bottom of the boron implanting region 12 (see FIG. 3A). This high-concentration aluminum implanting region 14 is designed to have a box profile having a depth of up to approximately 0.5 μm to 0.7 μm, with an ion implantation concentration of 1×10¹⁶ cm⁻³ to 1×10²⁰ cm⁻³, more specifically, 1×10²⁰ cm⁻³, for example, and an acceleration energy of 100 keV to 800 keV, more specifically, 300 keV to 400 keV, for example. This high-concentration aluminum implanting region 14 is connected to the p-type contact region 8 (see FIG. 3A). Although aluminum ions are implanted to a region shallower than the boron region in this example, the arrangement is not limited to this example in terms of relative depth. The ultimate boron diffusion region should be deeper than the aluminum region. Also, the high-concentration aluminum implanting region 14 formed in this step is disposed to protect the bottom portion of a high-concentration n-type region 18 to serve as a source contact region formed in a later step (see FIG. 4A). This is to prevent source-drain short-circuiting that occurs when the boron used to form the p-type region stops functioning as a p-type due to a dynamic punchthrough effect.

The oxide film mask 10 is not removed, and an aluminum film 16 of approximately 1 μm in thickness is formed on the substrate surface (see FIG. 3B). The aluminum film 16 is then patterned by a photolithography technique, so as to form aluminum masks 16a and 16b having openings 17 above the region to serve as the n-type source contact region (see FIG. 3C). The patterning of the aluminum film 16 is performed with RIE using a chlorine-based gas. In this embodiment, the aluminum film 16b remains on the oxide film mask 10, as shown in FIG. 3C. However, it is not necessary to have the aluminum film 16b remaining on the oxide film mask 10, and the oxide film mask 10 alone can function to prevent ion implantation in the step of ion implantation for forming the n-type source contact region. Also, the aluminum film 16 is patterned so that the aluminum film mask 16a remains on the p-type contact region 8. However, the aluminum film mask 16a does not need to have the same size as the p-type contact region 8.

Next, using the aluminum film mask 16a, multi-stage implantation of n-type impurity ions (such as phosphorus ions) is carried out so as to form an n-type source region 18 (see FIG. 4A). This n-type source region 18 is designed to have a box profile having a depth of up to approximately 0.4 μm, with an ion implantation concentration of 1×10¹⁶ cm⁻³ to 1×10²¹ cm⁻³, more specifically, 1×10²⁰ cm⁻³, for example, and a maximum acceleration energy of 100 keV to 400 keV, more specifically, 200 keV, for example. Phosphorus ions are then implanted to the bottom surface of the substrate 2, so as to form an n-type drain contact region 20 (see FIG. 4A). The n-type impurity ions used here may be nitrogen (N) ions, other than phosphorus ions.

Next, the substrate 2 is washed with a mixed acid of sulfuric acid and hydrogen peroxide solution, and the resist remaining on the aluminum film masks 16a and 16b and the substrate 2 is removed. The aluminum film masks 16a and 16b and the substrate 2 are then rinsed with pure water. The very small amount of metal impurities remaining on the substrate 2 are removed with a mixed acid of dilute hydrochloric acid and hydrogen peroxide solution, and the substrate 2 is rinsed with pure water. Lastly, the oxide film mask 10 is removed from the substrate surface with dilute hydrofluoric acid, and the substrate 2 is rinsed with pure water. In the case where the oxide film mask 10 is simply formed by widening the opening of the oxide film mask 6, the sacrifice oxide film formed on the surface of the epitaxial layer 4 is removed at the same time as the removal of the oxide film mask. The cleaned substrate 2 is introduced into an induction-heating activation annealing furnace that is vacuumed to an ultimate vacuum of 1×10⁻⁴ Pa. The activation annealing furnace is then filled with an Ar gas as an inert gas, and activation annealing is performed at 1500° C. to 1800° C. for 5 minutes to 2 hours. In this embodiment, 5-minute activation annealing at 1600° C. is performed. Through the activation annealing, boron is thermally diffused from the boron implanting region 12, so as to form a p-type base region 15 consisting of the aluminum implanting region 14 and a low-resistance boron diffusion region 12a to cover the aluminum implanting region 14 (see FIG. 4B). Here, a boron diffusion region 12b is formed on a side of the n-type source region 18 through the boron thermal diffusion in the boron implanting region 12, and the boron diffusion region 12b is to serve as a channel region 13 as later described.

After the substrate surface is thermally oxidized again, a silicon oxide (SiO₂) film 22 is formed on the substrate surface by CVD, as shown in FIG. 4C. The silicon oxide film 22 is then sintered in an Ar atmosphere at 1000° C. A resist pattern 24 having an opening 24a above the source region is then formed on the silicon oxide film 22 (see FIG. 4C).

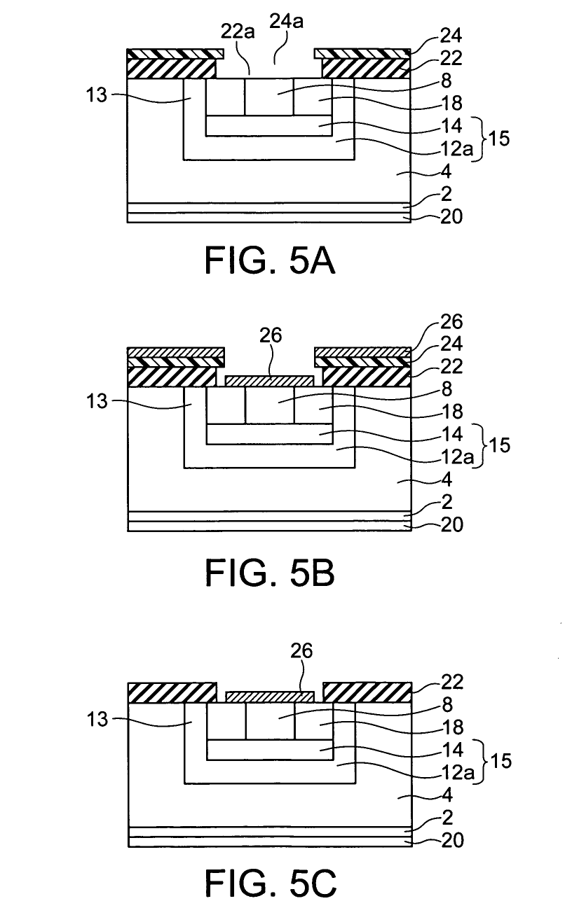

With the resist pattern 24 serving as a mask, the silicon oxide film 22 is etched with buffered hydrofluoric acid, so as to form an opening 22a in the silicon oxide film 22 (see FIG. 5A). This opening 22a is larger than the opening 24a of the resist pattern 24. The silicon oxide film 22 remaining through the etching functions as an insulating gate film. The boron diffusion region 12b below the insulating gate film 22, which is the boron diffusion region 12b on a side of the source region 18, serves as the channel region 13.

After a Ni film 26 with a thickness of 40 nm is formed by electron gun deposition or sputtering (see FIG. 5B), the resist pattern 24 is removed with acetone, and at the same time, the portions of the Ni film 26 located on the resist pattern 24 is lifted off, so that the Ni film 26 to serve as a source electrode remains selectively in the source region (see FIG. 5C). Sintering is then performed in an Ar atmosphere at 1000° C. for one minute, so that ohmic contact occurs in the source region.

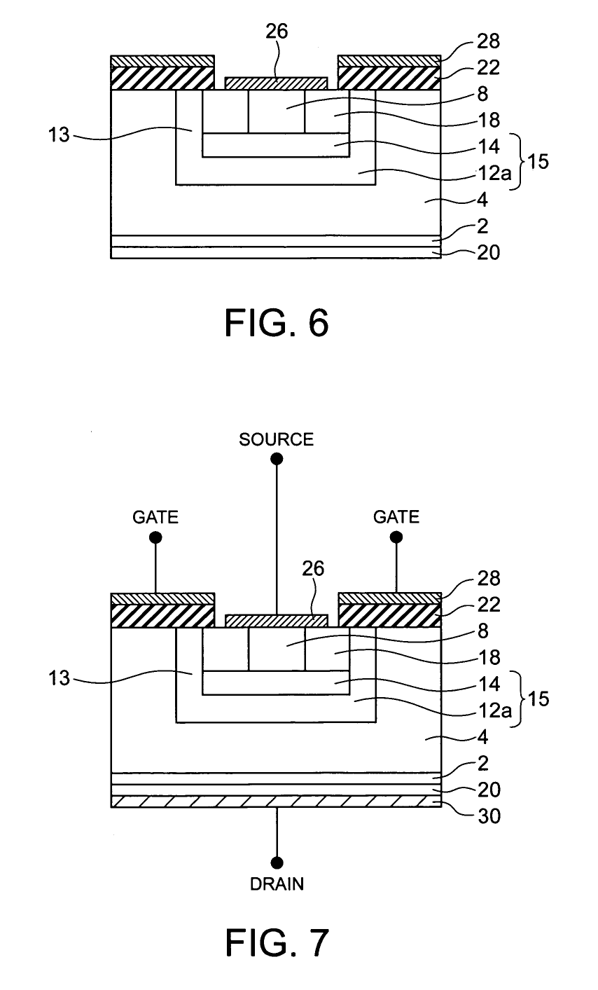

Using a lithography technique, gate electrodes 28 made of Ti are formed only on the insulating gate film 22 (see FIG. 6). The substrate surface is then protected with resist, and a bottom-face electrode 30 made of Ti/Ni/Au is formed so as to be in contact with the n-type contact region 20 on the bottom surface of the substrate 2 (see FIG. 7). A passivation film (not shown) is then formed for protection, thereby completing a SiC insulated gate transistor. Although the only one source electrode 26 and the only two gate electrodes 28 are shown in FIG. 7, the source electrodes 26 and the gate electrodes 28 are alternately arranged in practice. More specifically, the source electrode, the p-type contact region, the source region, and the p-type base region shown in the center of FIG. 7 are formed on the right side of the right-side gate electrode 28 in FIG. 7. Meanwhile, the source electrode, the p-type contact region, the source region, and the p-type base region shown in the center of FIG. 7 are formed also on the left side of the left-side gate electrode 28 in FIG. 7.

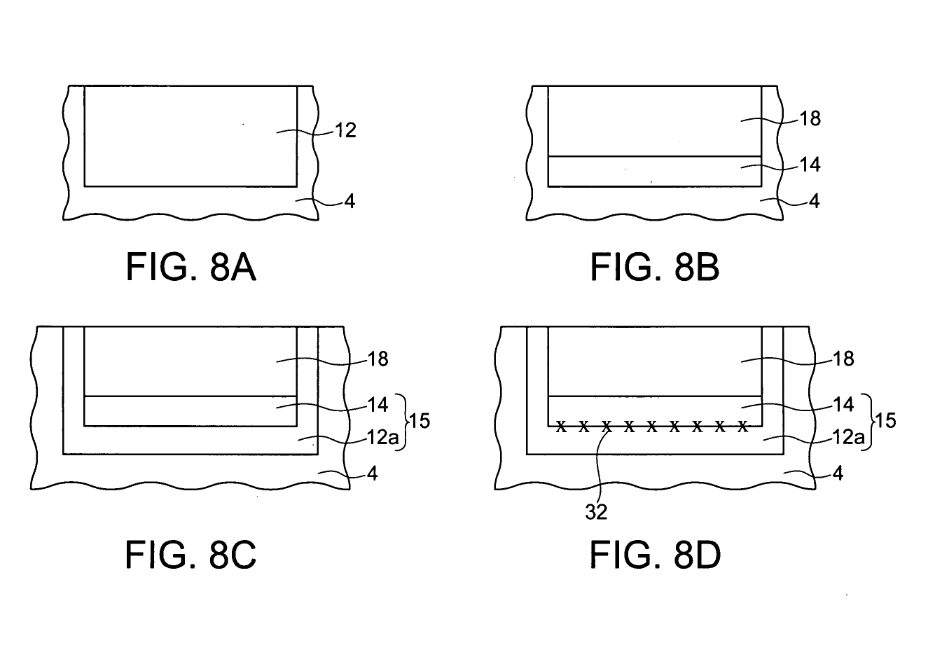

In this embodiment, as shown in FIG. 8A, the formation of the p-type base region 15 is carried out by first forming the boron ion implanting region 12 on the n-type epitaxial layer 4 to serve as a drift region, using a mask (not shown). Using the same mask, the aluminum ion implanting region 14 is formed, and n-type impurities are injected so as to form the source region 18 (see FIG. 8B). As shown in FIG. 8C, the boron ions are diffused deeper than the bottom portion of the aluminum implanting region 14 through thermal treatment. Accordingly, the boron diffusion region 12a covers a defective portion 32 formed through the aluminum ion implantation (at the bottom portion of the aluminum implanting region 14) (see FIG. 8D). Thus, alleviation of the electric field concentrating on the crystalline defect due to the ion implantation at the interface between the drift region 4 and the base region 15 becomes possible, and a decrease in breakdown voltage can be effectively restricted.

Since the aluminum implanting region 14 that has a larger area than the area of the lower face of the source electrode 26 and covers the source electrode 26 from the below is interposed between the boron diffusion region 12a and the source region 18 (see FIG. 8D), the dynamic punchthrough can be restricted. Also, charging and discharging of carriers (electrons) in the depletion layer of the n-type drift layer at the times of switching on and off can be restricted, and the variation in potential at the times of charging and discharging of holes in the p-type base region can be made smaller.

Further, the n-type conductive impurities (such as phosphorus and nitrogen) forming the source region 18 may have a smaller thermal diffusion coefficient than boron in SiC. The n-type conductive ion implantation and the boron ion implantation may be carried out using the same ion implanting mask, and boron may be thermally diffused in a later heating step. In such a case, the n-type conductive impurity region 18 to serve as the source region is self-aligned inside the p-type base region 15 of boron. Thus, misalignment can be avoided.

As the p-type region 13 below the insulating gate film 22 formed through boron diffusion is used as the channel region, crystalline defects in the channel region can be restricted, and carrier scattering can be restrained. Thus, a low ON resistance can be achieved.

Although aluminum, boron, and phosphorus ions are implanted using the same mask in this embodiment, it is not necessary to use the same mask.

### Second Embodiment

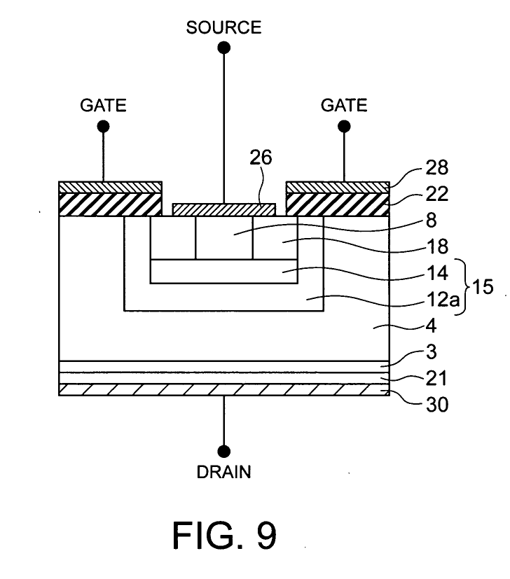

Referring now to FIG. 9, a SiC insulated gate transistor according to a second embodiment of the present invention is described. The SiC insulated gate transistor of this embodiment is an IGBT (Insulated Gate Bipolar Transistor). The SiC insulated gate transistor of this embodiment differs from the SiC insulated gate transistor of the first embodiment in that the n-type SiC substrate 2 is replaced with a p-type SiC substrate 3 and the n-type drain contact region 20 is replaced with a p-type drain contact region 21. The p-type drain contact region 21 is formed by implanting p-type impurity ions (such as aluminum ions). The thickness and concentration of the drift layer of the IGBT, which is a bipolar device, are set within ±50% (more preferably ±20%) of the optimum conditions described in First Embodiment.

This embodiment of course has the same effects as those of the first embodiment.

Although all the boron ions are diffused deeper than the aluminum impurity region in the first and second embodiments, it is not necessary to have the boron ions diffused deeper than the aluminum impurity region, with the breakdown voltage being taken into consideration.

### Third Embodiment

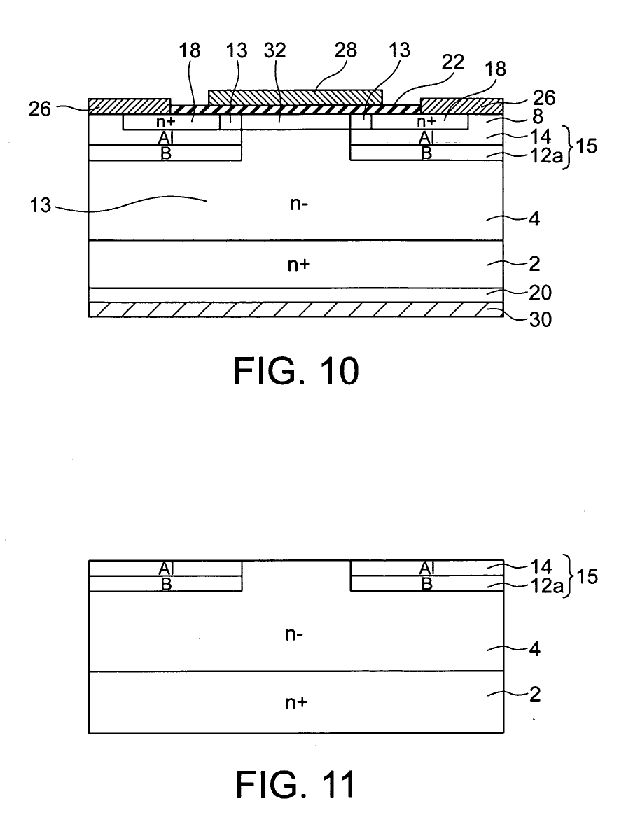

Referring now to FIGS. 10 through 16, a SiC insulated gate transistor according to a third embodiment of the present invention is described. FIG. 10 is a cross-sectional view of the SiC insulated gate transistor of this embodiment, and FIGS. 11 through 16 are cross-sectional views illustrating manufacturing procedures.

The SiC insulated gate transistor illustrated in FIG. 10 is the same as the SiC insulated gate transistor of the first embodiment illustrated in FIG. 7, except that a gate electrode 28 is shown in the middle among the alternately arranged source electrodes 26 and gate electrodes 28. In FIG. 7, a source electrode 26 is shown in the middle. In FIG. 10, an n-type region 32 having nitrogen (N) ions implanted thereto is formed in the region located between end faces of the p-type base regions 15 sandwiching the gate electrode 28. The regions between the n-type region 32 and the source regions 18 are channel regions 13 that contain p-type impurities and are formed through epitaxial growth.

Like the SiC insulated gate transistor of the first embodiment, the SiC insulated gate transistor of this embodiment has a SiC semiconductor layer with the p-type base region 15 that forms a main junction with the n-type drift layer 4 and contains aluminum and boron elements. In this structure, at least the bottom surface of each aluminum region 14 containing mostly aluminum is covered with the region 12a containing boron. In other words, the concentration profile of aluminum in the depth direction is designed to be equal to or shallower than the profile of boron in the depth direction.

Also like the first embodiment, each aluminum region 14 has a larger area than the area of the bottom face of each source electrode 26, and a shadow of each source electrode 26 cast from the element surface always falls within the corresponding aluminum region 14, so as to prevent a dynamic punchthrough effect. Furthermore, the area of each aluminum region 14 is larger than the contact area between each source electrode 26 and each corresponding p-type contact region 8 and each corresponding source region 18, and shadows of each source electrode 26 and each source region 18 cast from the element surface always fall within the corresponding aluminum region 14.

As described above, in this embodiment, the channel regions 13 are formed with a p-type epitaxial layer. If p-type regions formed through ion implantation and containing many crystalline defects are used as channels, electron scattering is caused due to the crystalline defects in inverse regions, when a bias is applied to the gate to form an inverse layer that is put in an ON state. The mobility then decreases, and the ON resistance increases. Therefore, the p-type channel regions are formed with an epitaxial layer, as in this embodiment. With this structure, the number of crystalline defects is greatly reduced, and an increase in ON resistance can be restricted.

Referring now to FIGS. 11 through 17, the method of manufacturing the SiC insulated gate transistor of this embodiment is described.

As shown in FIG. 11, a low-concentration n-type epitaxial layer 4 is first formed on a substrate 2 made of n-type SiC. Multi-stage implantation of boron and aluminum ions is carried out, so as to form a p-type base region 15 consisting of a boron region 12 and an aluminum region 14.

This boron implanting region is designed to have a box profile having a depth of up to approximately 1 μm, with an ion implantation concentration of 1×10¹⁶ cm⁻³ to 1×10²⁰ cm⁻³, more specifically, 1×10¹⁸ cm⁻³, for example, and a maximum acceleration energy of 200 keV to 800 keV, more specifically, 400 keV, for example. The boron implanting region may have a box profile with a depth up to approximately 1 μm from the substrate surface. However, the boron is thermally diffused through an activation anneal in a later step. Therefore, it is not necessary to implant ions in the region of 0.3 μm to 0.5 μm from the substrate surface. With the thermal diffusion of boron being taken into consideration, the boron region 12a should become deeper than the aluminum implanting region 14 after the diffusion, and accordingly, the maximum acceleration energy for the boron ion implantation may be approximately 320 keV.

After the boron implanting region is formed, multi-stage implantation of aluminum ions is carried out so as to form the high-concentration aluminum implanting region 14 at the bottom of the boron implanting region. This high-concentration aluminum implanting region 14 is designed to have a box profile having a depth of up to approximately 0.5 μm to 0.7 μm, with an ion implantation concentration of 1×10¹⁶ cm⁻³ to 1×10²⁰ cm⁻³, more specifically, 1×10²⁰ cm⁻³, for example, and an acceleration energy of 100 keV to 800 keV, more specifically, 300 keV to 400 keV, for example. Although aluminum ions are implanted to a region shallower than the boron region in this example, the arrangement is not limited to this example in terms of relative depth. The ultimate boron diffusion region should be deeper than the aluminum implanting region 14. Also, the high-concentration aluminum implanting region 14 formed in this step is disposed to protect the bottom portion of a high-concentration n-type region to serve as a source region 18 to be formed in a later step. This is to prevent source-drain short-circuiting that occurs when the boron used to form the p-type base region 15 stops functioning as a p-type due to a dynamic punchthrough effect.

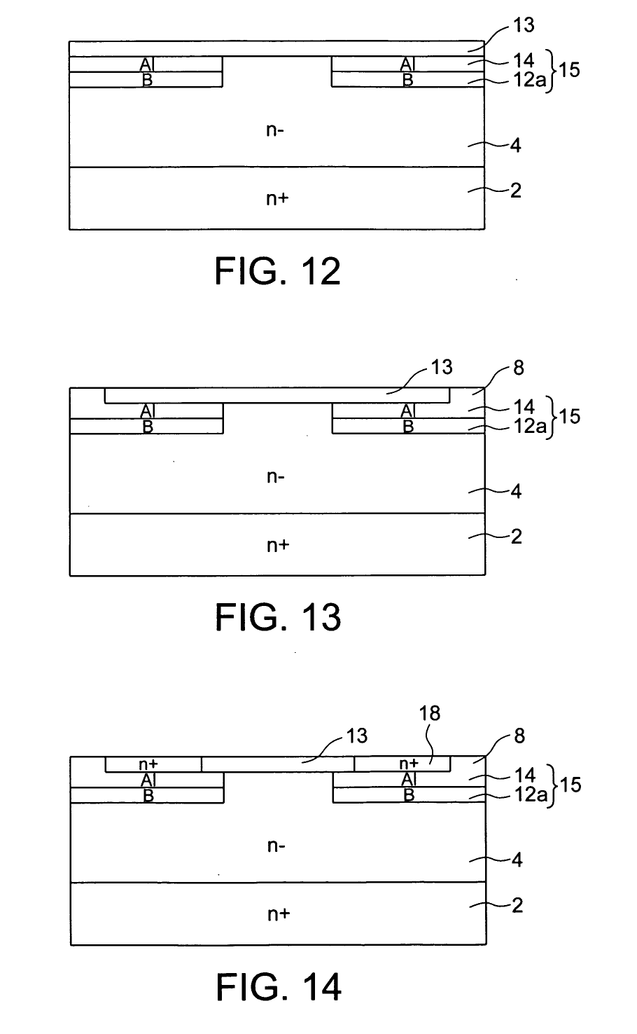

Next, a p-type epitaxial layer 13 made of p-type SiC is formed on the substrate surface through epitaxial growth, as shown in FIG. 12. Al ions are then selectively implanted from the surface of the epitaxially-grown p-type layer 13, so as to form contact regions 8 in contact with the aluminum regions 14, as shown in FIG. 13.

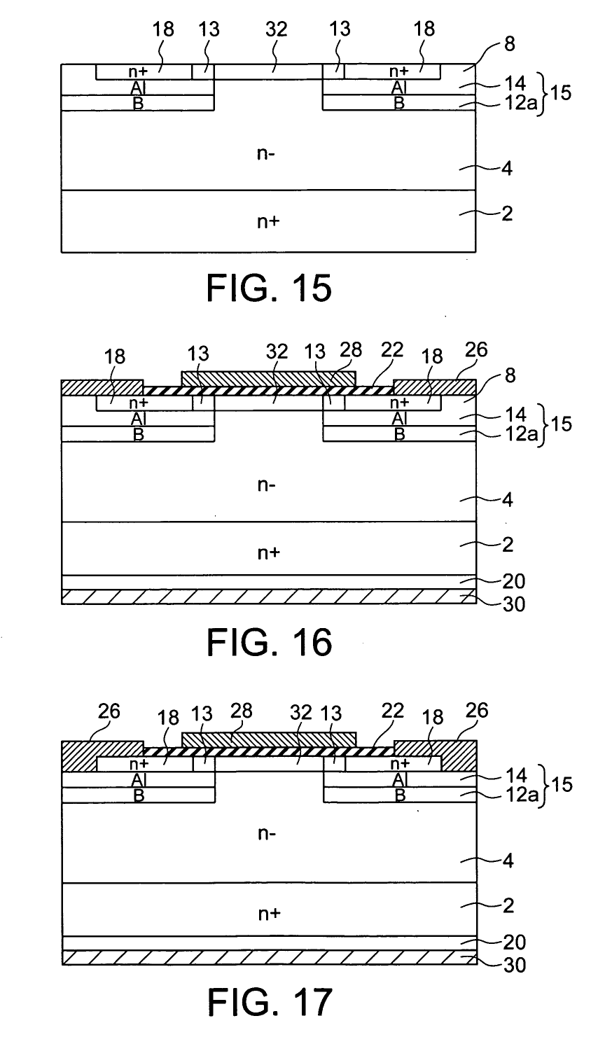

Next, phosphorus ions are selectively implanted to the p-type epitaxial layer 13, so as to form n-type regions 18 to serve as a source region (see FIG. 14). Ion implantation using nitrogen (N), for example, is then selectively carried out, so as to turn the region adjacent to the channels into an n-type region 32 (see FIG. 15). The ion implantation is carried out in such a manner that the conductivity type of the region 32 becomes the n-type.

So as to reduce the ohmic contact on the bottom surface, annealing is carried out to activate implanted impurity ions after high-concentration phosphorus ions are implanted to the bottom surface, and a contact region 20 is formed (see FIG. 16). A gate insulating film 22 is then formed on the substrate surface, and source electrodes 26 and gate electrodes 28 are selectively formed. At the same time, a drain electrode 30 is formed on the bottom face of the substrate 2, thereby completing the SiC insulated gate transistor of the third embodiment (see FIG. 16).

As described above, the contact region 8 connecting the source electrodes 26 to the p-type base regions 15 is formed by implanting Al ions as shown in FIG. 13. However, the portions of the substrate surface in contact with the source electrodes 26 are the p-type epitaxial layer 13. Therefore, it is not necessary to implant Al ions.

As a modification of this embodiment, the aluminum regions 14 may be connected directly to the source electrodes 26, as shown in FIG. 17. In this case, instead of forming the contact region 8 by implanting Al ions to the p-type epitaxial layer 13, part of the p-type epitaxial layer 13 is etched after the source regions 18 are formed, and the source electrodes 26 are then formed.

As described above, like the first embodiment, this embodiment and the modification can most effectively prevent a decrease in breakdown voltage, and restrict a dynamic punchthrough effect. Also, charging and discharging of carriers (electrons) in the depletion layer of the n-type drift layer at the times of switching on and off can be restricted, and the variation in potential at the times of charging and discharging of holes in the p-type base region can be made smaller.

### Fourth Embodiment

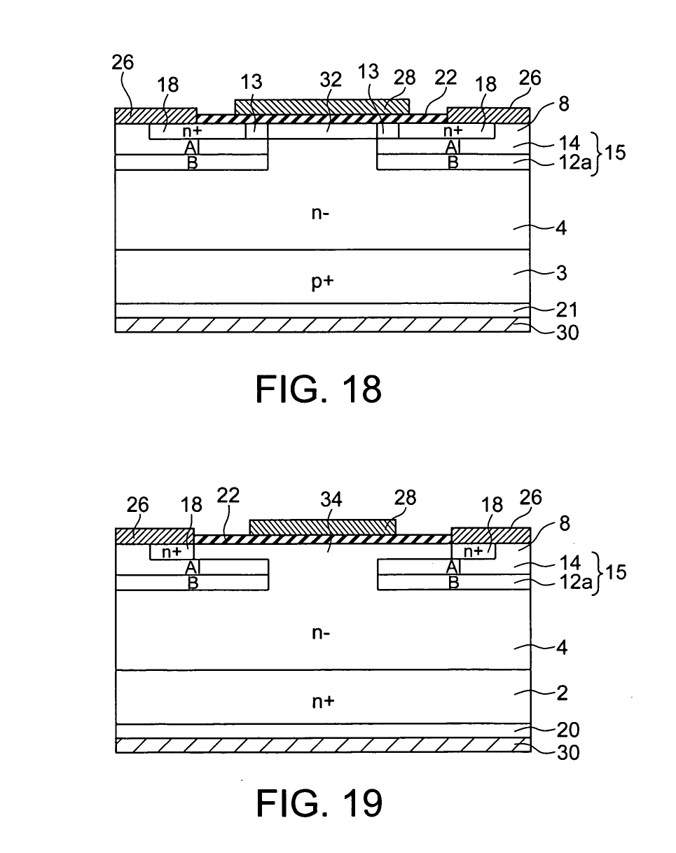

Referring now to FIG. 18, a SiC insulated gate transistor according to a fourth embodiment of the present invention is described. The SiC insulated gate transistor of this embodiment is an IGBT. The SiC insulated gate transistor of this embodiment differs from the SiC insulated gate transistor of the third embodiment in that the n-type SiC substrate 2 is replaced with a p-type SiC substrate 3 and the n-type drain contact region 20 is replaced with a p-type drain contact region 21. The p-type drain contact region 21 is formed by implanting p-type impurity ions (such as aluminum ions). The thickness and concentration of the drift layer of the IGBT, which is a bipolar device, are set within ±50% (more preferably ±20%) of the optimum conditions described in First Embodiment.

Like the third embodiment, this embodiment can most effectively prevent a decrease in breakdown voltage, and restrict dynamic punchthrough.

### Fifth Embodiment

Referring now to FIG. 19, a SiC insulated gate transistor according to a fifth embodiment of the present invention is described.

The SiC insulated gate transistor of this embodiment is the same as the SiC insulated gate transistor of the third embodiment, except that the p-type region 13 and the n-type region 32 are replaced with an n-type region 34. In an OFF state of this structure, a current is cut off by extending the depletion layer from the gate insulating film 22 in a thermal equilibrium state or by actively applying a negative bias to the gate electrodes 28 to extend the depletion layer to the channel region 34. In an ON state, a storage region is formed in the vicinity of the gate insulating film 22 by shortening the depletion layer of the channel region 34 to let a current flow or by actively applying a positive bias to the gate. Thus, the ON resistance can be further reduced.

Like the SiC insulated gate transistor of the third embodiment, the SiC insulated gate transistor of this embodiment has a SiC semiconductor layer with the p-type base region 15 that forms a main junction with the n-type drift layer 4 and contains aluminum and boron elements. In this structure, at least the bottom surface of each aluminum region 14 containing mostly aluminum is covered with the region 12a containing boron. In other words, the concentration profile of aluminum in the depth direction is designed to be equal to or shallower than the profile of boron in the depth direction.

Also like the first embodiment, each aluminum region 14 has a larger area than the area of the bottom face of each source electrode 26, and a shadow of each source electrode 26 cast from the element surface always falls within the corresponding aluminum region 14, so as to prevent a dynamic punchthrough effect. Furthermore, the area of each aluminum region 14 is larger than the contact area between each source electrode 26 and each corresponding p-type contact region 8 and each corresponding source region 18, and shadows of each source electrode 26 and each corresponding source region 18 cast from the element surface always fall within the corresponding aluminum region 14.

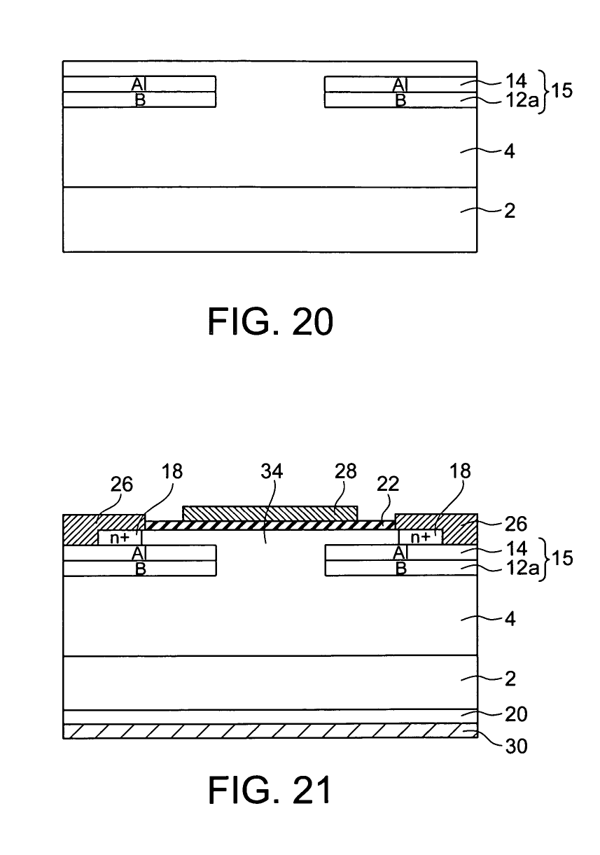

As shown in FIG. 20, the formation of the SiC insulated gate transistor of this embodiment is first carried out by forming the p-type base regions 15 each consisting of the boron region 12a and the aluminum region 14 in the n-type drift layer 4 only through ion implantation. At the time of the ion implantation, such a kind of energy should be selected that the substrate surface can maintain the n-type conductivity. The manufacturing steps thereafter are the same as those of the third embodiment, except that the step of forming the p-type epitaxial layer 13 and the n-type region 32 is skipped.

As described in Third Embodiment, it is not necessary to implant Al ions for forming the contact regions 8 to connect the aluminum regions 14 of the p-type base regions 15 and the source electrodes 26.

As shown in FIG. 21, in a modification of this embodiment, the aluminum regions 14 may be connected directly to the source electrodes 26. In this case, instead of forming the contact regions 8 by implanting Al ions to the p-type epitaxial layer 13, part of the n-type layer 34 is etched after the source regions 18 are formed, and the source electrodes 26 are then formed.

As described above, like the first embodiment, this embodiment and the modification can most effectively prevent a decrease in breakdown voltage, and restrict a dynamic punchthrough effect.

### Sixth Embodiment

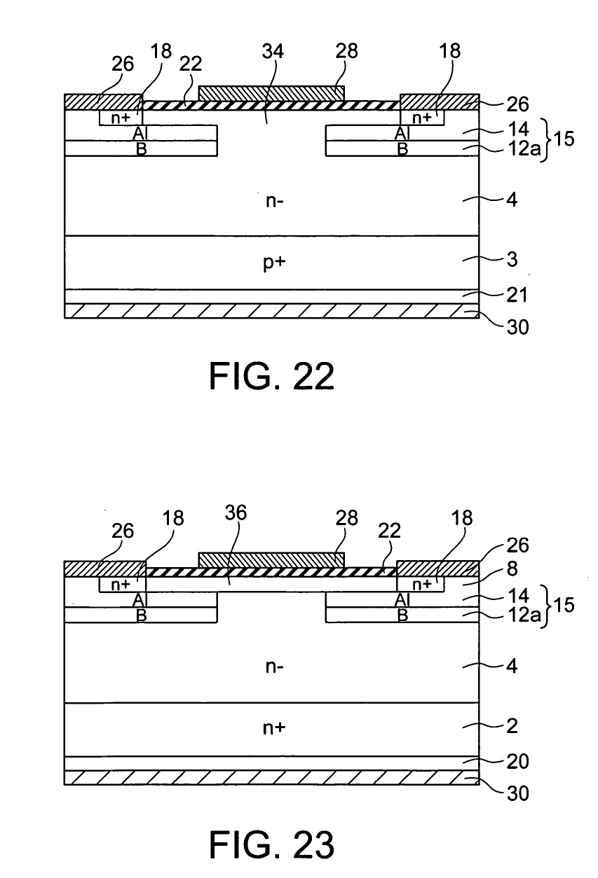

Referring now to FIG. 22, a SiC insulated gate transistor according to a sixth embodiment of the present invention is described. The SiC insulated gate transistor of this embodiment is an IGBT. The SiC insulated gate transistor of this embodiment differs from the SiC insulated gate transistor of the fifth embodiment in that the n-type SiC substrate 2 is replaced with a p-type SiC substrate 3 and the n-type drain contact region 20 is replaced with a p-type drain contact region 21. The p-type drain contact region 21 is formed by implanting p-type impurity ions (such as aluminum ions). The thickness and concentration of the drift layer of the IGBT, which is a bipolar device, are set within ±50% (more preferably ±20%) of the optimum conditions described in First Embodiment.

Like the fifth embodiment, this embodiment can most effectively prevent a decrease in breakdown voltage, and restrict dynamic punchthrough.

### Seventh Embodiment

Referring now to FIG. 23, a SiC insulated gate transistor according to a seventh embodiment of the present invention is described.

The SiC insulated gate transistor of this embodiment is the same as the SiC insulated gate transistor of the fifth embodiment, except that the n-type layer 34 is replaced with an n-type epitaxial layer 36. Accordingly, the principles of ON and OFF operations are the same as those of the fifth embodiment.

In the fifth embodiment, defects are caused on the substrate surface, because ion implantation is carried out to form the p-type base region 15. This increases the carrier scattering, and reduces the carrier mobility, resulting in an increase in ON resistance. In the seventh embodiment, however, the channel regions are formed through n-type epitaxial regrowth. Thus, the defect density decreases, and an increase in ON resistance is restricted.

Like the SiC insulated gate transistor of the fifth embodiment, the SiC insulated gate transistor of this embodiment has a SiC semiconductor layer with the p-type base region 15 that forms a main junction with the n-type drift layer 4 and contains aluminum and boron elements. In this structure, at least the bottom surface of each aluminum region 14 containing mostly aluminum is covered with the region 12a containing boron. In other words, the concentration profile of aluminum in the depth direction is designed to be equal to or shallower than the profile of boron in the depth direction.

Also like the first embodiment, each aluminum region 14 has a larger area than the area of the bottom face of each source electrode 26, and a shadow of each source electrode 26 cast from the element surface always falls within the corresponding aluminum region 14, so as to prevent a dynamic punchthrough effect. Furthermore, the area of each aluminum region 14 is larger than the contact area between each source electrode 26 and the corresponding p-type contact region 8 and the corresponding source region 18, and shadows of each source electrode 26 and the corresponding source region 1-8 cast from the element surface always fall within the corresponding aluminum region 14.

The formation of the SiC insulated gate transistor of this embodiment is carried out in the same manner as in the third embodiment, except that the p-type epitaxial growth is replaced with n-type epitaxial growth, and the step of forming the n-type region 32 is skipped.

As described in Third Embodiment, it is not necessary to implant Al ions for forming the contact regions 8 to connect the aluminum regions 14 of the p-type base regions 15 and the source electrodes 26.

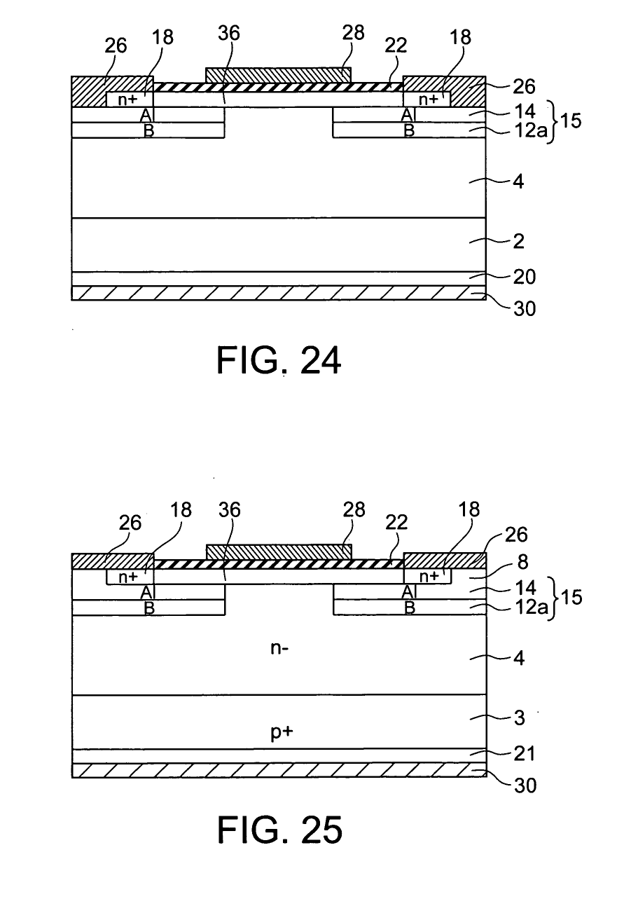

As shown in FIG. 24, in a modification of this embodiment, the aluminum regions 14 may be connected directly to the source electrodes 26. In this case, instead of forming the contact region 8 by implanting Al ions to the p-type epitaxial layer 13, part of the n-type epitaxial layer 36 is etched after the source regions 18 are formed, and the source electrodes 26 are then formed.

As described above, like the first embodiment, this embodiment and the modification can most effectively prevent a decrease in breakdown voltage, and restrict a dynamic punchthrough effect.

### Eighth Embodiment

Referring now to FIG. 25, a SiC insulated gate transistor according to an eighth embodiment of the present invention is described. The SiC insulated gate transistor of this embodiment is an IGBT. The SiC insulated gate transistor of this embodiment differs from the SiC insulated gate transistor of the seventh embodiment in that the n-type SiC substrate 2 is replaced with a p-type SiC substrate 3 and the n-type drain contact region 20 is replaced with a p-type drain contact region 21. The p-type drain contact region 21 is formed by implanting p-type impurity ions (such as aluminum ions). The thickness and concentration of the drift layer of the IGBT, which is a bipolar device, are set within ±50% (more preferably ±20%) of the optimum conditions described in First Embodiment.

Like the seventh embodiment, this embodiment can most effectively prevent a decrease in breakdown voltage, and restrict dynamic punchthrough.

### Ninth Embodiment

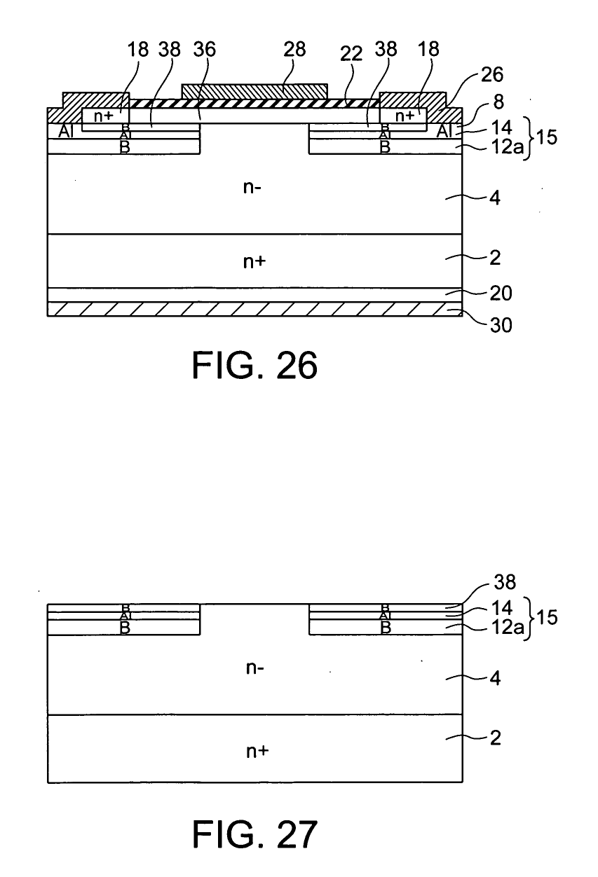

Referring now to FIG. 26, a SiC insulated gate transistor according to a ninth embodiment of the present invention is described.

The SiC insulated gate transistor of this embodiment is the same as the SiC insulated gate transistor of the seventh embodiment, except that a boron layer 38 is interposed between each aluminum layer 14 and the n-type epitaxial layer 36. Accordingly, the principles of ON and OFF operations are the same as those of the seventh embodiment.

Where the aluminum layers 14 are on the surfaces of the p-type base regions 15 at the time of forming the n-type epitaxial layer 36 to be the channel region, as in the seventh embodiment illustrated in FIG. 23, many crystalline defects caused by ion implantation remain to degrade the crystallinity of the epitaxial layer that is to be grown thereon. Therefore, a boron layer 38 is formed on the surface of each p-type base region 15 through ion implantation in this embodiment. Thus, the number of crystalline defects due to ion implantation is reduced, and the crystallinity of the epitaxial layer 36 can be improved.

The formation of the SiC insulated gate transistor of this embodiment is carried out in the same manner as in the seventh embodiment, except that, after the p-type base regions 15 each consisting of a boron layer 12a and an aluminum layer 14 are formed, the boron layers 38 are formed by implanting boron ions onto the aluminum layers 14, as shown in FIG. 27.

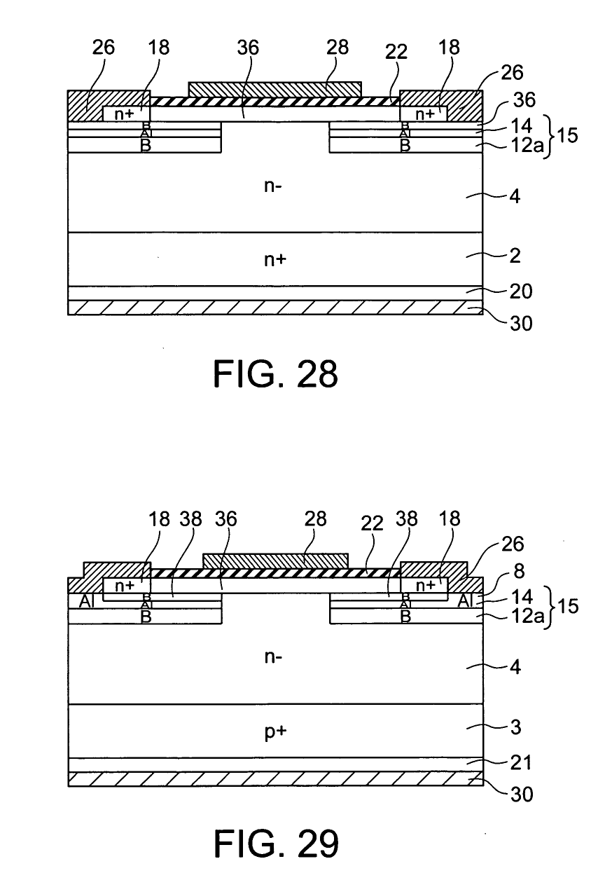

As shown in FIG. 28, in a modification of this embodiment, the aluminum regions 14 may be connected directly to the source electrodes 26. In this case, instead of forming the contact regions 8 by implanting Al ions to the n-type epitaxial layer 36, part of the n-type epitaxial layer 36 is etched after the source regions 18 are formed, and the source electrodes 26 are then formed.

As described above, like the seventh embodiment, this embodiment and the modification can most effectively prevent a decrease in breakdown voltage, and restrict a dynamic punchthrough effect.

### Tenth Embodiment

Referring now to FIG. 29, a SiC insulated gate transistor according to a tenth embodiment of the present invention is described. The SiC insulated gate transistor of this embodiment is an IGBT. The SiC insulated gate transistor of this embodiment differs from the SiC insulated gate transistor of the ninth embodiment in that the n-type SiC substrate 2 is replaced with a p-type SiC substrate 3 and the n-type drain contact region 20 is replaced with a p-type drain contact region 21. The p-type drain contact region 21 is formed by implanting p-type impurity ions (such as aluminum ions). The thickness and concentration of the drift layer of the IGBT, which is a bipolar device, are set within ±50% (more preferably ±20%) of the optimum conditions described in First Embodiment.

Like the ninth embodiment, this embodiment can most effectively prevent a decrease in breakdown voltage, and restrict dynamic punchthrough.

### Eleventh Embodiment

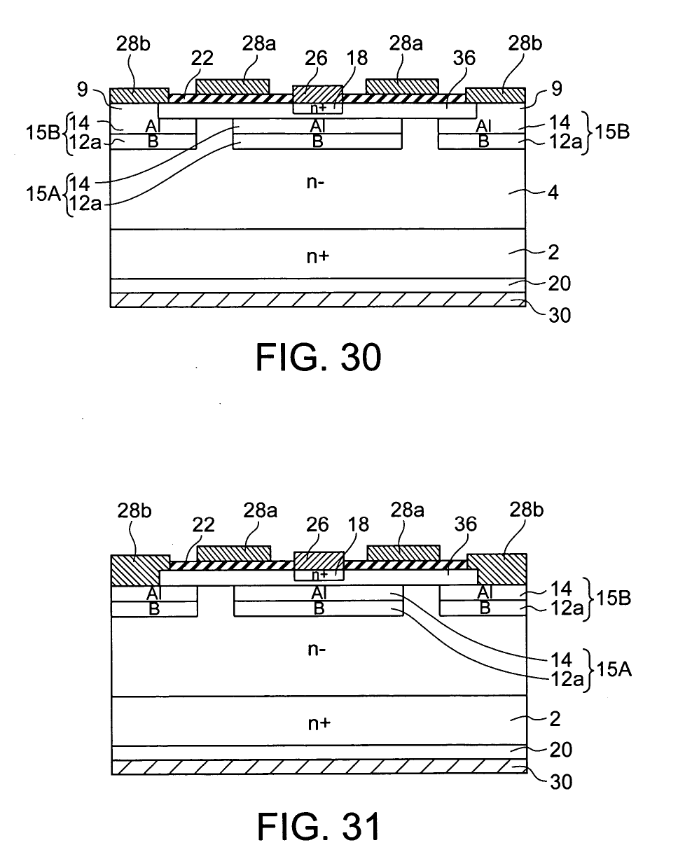

Referring now to FIG. 30, a SiC insulated gate transistor according to an eleventh embodiment of the present invention is described. FIG. 30 is a cross-sectional view of the SiC insulated gate transistor of this embodiment.

The SiC insulated gate transistor of this embodiment has p-type regions 15A and 15B separated from each other on the surface of an n⁻ drift layer 4 formed on an n-type SiC substrate 2. The p-type regions 15A and 15B each have a boron region 12a and an aluminum region 14. An n-type epitaxial layer 36 is formed to cover the entire upper surface of each p-type region 15A, part of the upper surface of each p-type region 15B, and the portions of the n⁻ drift layer 4 located between the p-type regions 15A and 15B. A gate insulating film 22 is formed on the n-type epitaxial layer 36. An n-type source region 18 is formed in the region located above each p-type region 15A and on the upper face side of the n-type epitaxial layer 36. A source electrode 26 to be connected to a source region is formed in each source region 18. First gate electrodes 28a are formed in regions of the gate insulating film 22 that are located above the portions of the n⁻ drift layer 4 between the p-type regions 15A and 15B. Second gate electrodes 28b are formed above the p-type regions 15B via p-type contact regions 9. The first gate electrodes 28a are formed so as to cover the entire portions of the n⁻ drift layer 4 between the p-type regions 15A and 15B. The p-type contact regions 9 are formed by implanting aluminum ions. An n-type contact region 20 is formed on the bottom face of the n-type substrate 2, and a bottom-face electrode 30 is formed in contact with the n-type contact region 20.

The p-type regions 15A and 15B are designed to have the boron regions 12a covering at least the bottom faces of the aluminum regions 14. Accordingly, the concentration profile of aluminum in the depth direction is designed to be equal to or shallower than the profile of boron in the depth direction.

The aluminum region 14 of each p-type regions 15A has a larger area than the area of the bottom face of each source electrode 26, and a shadow of each source electrode 26 cast from the element surface always falls within the corresponding aluminum region 14, so as to prevent a dynamic punchthrough effect. Furthermore, the film area of each aluminum region 14 is larger than the contact area between each source electrode 26 and each corresponding source region 18, and shadows of each source electrode 26 and the corresponding source region 18 cast from the element surface always fall within the aluminum region 14. Also, the film area of the aluminum region 14 of each p-type region 15B is larger than the lower face of each second gate electrode 28b, and a shadow of each second gate electrode 28b cast from the element surface always fall within the aluminum region 14 of the corresponding p-type region 15B.

When the transistor is put into an OFF state, a negative bias is applied to the second gate electrodes 28b, so as to extend a depletion layer. Here, a negative bias may also be applied to the first gate electrodes 28a.

When the transistor is put into an ON state, no bias is applied to the second gate electrodes 28b or a positive bias is applied to the second gate electrodes 28b, so as to shorten the depletion layer. Here, if the bias to be applied to the p-type regions 15B is 2.5 V or lower, the transistor functions as a unipolar device. If the bias to be applied to the p-type regions 15B is 2.5 V or higher, holes are injected through the p-type regions 15B.

A positive bias is applied to the first gate electrodes 26a, so that a storage layer can be formed in the vicinity of the gate insulating film 22 and the ON resistance can be further lowered.

In a modification of this embodiment, the aluminum regions 14 of the p-type regions 15B may be connected directly to the second gate electrodes 28b, as shown in FIG. 31.

As described above, this embodiment and the modification can most effectively prevent a decrease in breakdown voltage, and restrict dynamic punchthrough.

### Twelfth Embodiment

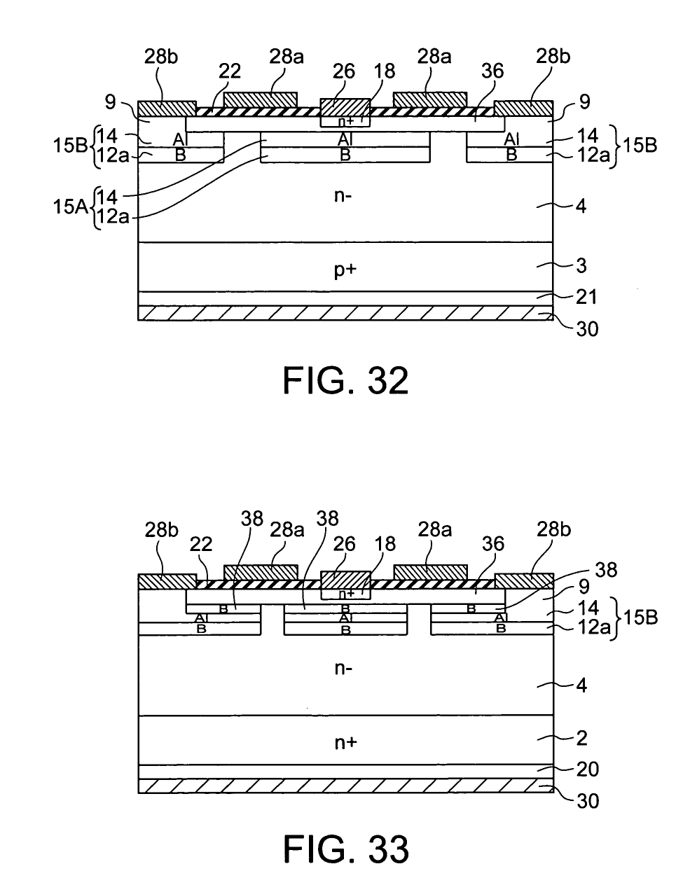

Referring now to FIG. 32, a SiC insulated gate transistor according to a twelfth embodiment of the present invention is described. The SiC insulated gate transistor of this embodiment is an IGBT. The SiC insulated gate transistor of this embodiment differs from the SiC insulated gate transistor of the eleventh embodiment in that the n-type SiC substrate 2 is replaced with a p-type SiC substrate 3 and the n-type drain contact region 20 is replaced with a p-type drain contact region 21. The p-type drain contact region 21 is formed by implanting p-type impurity ions (such as aluminum ions). The thickness and concentration of the drift layer of the IGBT, which is a bipolar device, are set within ±50% (more preferably ±20%) of the optimum conditions described in First Embodiment.

Like the eleventh embodiment, this embodiment can most effectively prevent a decrease in breakdown voltage, and restrict dynamic punchthrough.

### Thirteenth Embodiment

Referring now to FIG. 33, a SiC insulated gate transistor according to a thirteenth embodiment of the present invention is described. FIG. 33 is a cross-sectional view of the SiC insulated gate transistor of this embodiment.

The SIC insulated gate transistor of this embodiment is the same as the SiC insulated gate transistor of the eleventh embodiment, except that a boron layer 38 is interposed between each aluminum layer 14 of the p-type regions 15A and 15B and the n-type epitaxial layer 36. Accordingly, the principles of ON and OFF operations are the same as those of the eleventh embodiment.

Where the aluminum layers 14 are on the surfaces of the p-type base regions 15 at the time of forming the n-type epitaxial layer 36 to be the channel region, as in the eleventh embodiment illustrated in FIG. 30, many crystalline defects caused by ion implantation remain to degrade the crystallinity of the epitaxial layer that is to be grown thereon. Therefore, a boron layer 38 is formed on the surface of each p-type base region 15 through ion implantation in this embodiment. Thus, the number of crystalline defects due to ion implantation is reduced, and the crystallinity of the epitaxial layer 36 can be improved.

As in the modification of the eleventh embodiment, the aluminum regions 14 of the p-type regions 15B may be connected directly to the second gate electrodes, without the p-type contact regions 9.

Like the eleventh embodiment, this embodiment can most effectively prevent a decrease in breakdown voltage, and restrict a dynamic punchthrough effect.

### Fourteenth Embodiment

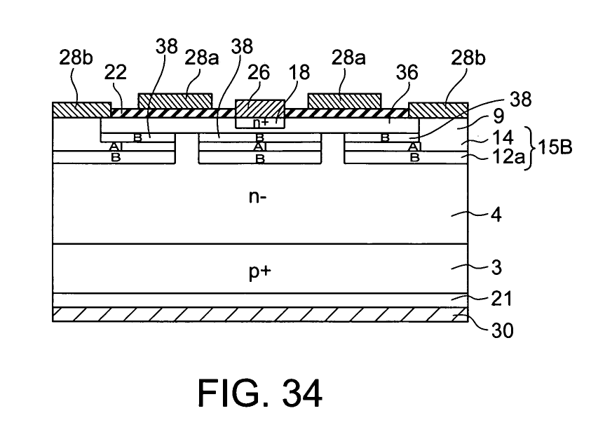

Referring now to FIG. 34, a SiC insulated gate transistor according to a fourteenth embodiment of the present invention is described. The SiC insulated gate transistor of this embodiment is an IGBT. The SiC insulated gate transistor of this embodiment differs from the SiC insulated gate transistor of the thirteenth embodiment in that the n-type SiC substrate 2 is replaced with a p-type SiC substrate 3 and the n-type drain contact region 20 is replaced with a p-type drain contact region 21. The p-type drain contact region 21 is formed by implanting p-type impurity ions (such as aluminum ions). The thickness and concentration of the drift layer of the IGBT, which is a bipolar device, are set within ±50% (more preferably ±20%) of the optimum conditions described in First Embodiment.

Like the thirteenth embodiment, this embodiment can most effectively prevent a decrease in breakdown voltage, and restrict dynamic punchthrough.

### Fifteenth Embodiment

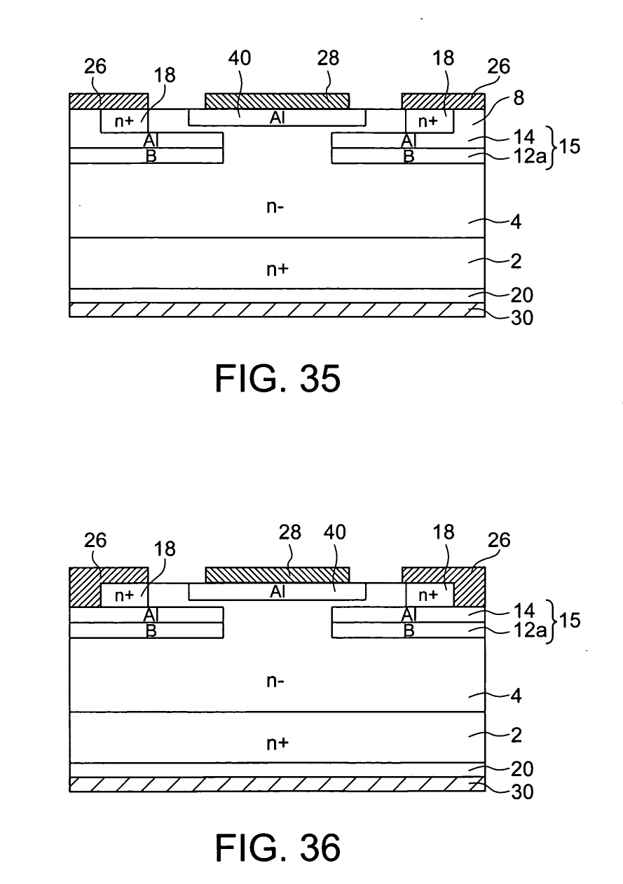

Referring now to FIG. 35, a SiC junction field-effect transistor (a static induction transistor) according to a fifteenth embodiment of the present invention is described. The SiC junction field-effect transistor (a static induction transistor) of this embodiment is the same as the transistor of the fifth embodiment illustrated in FIG. 19, except that the gate insulating film 22 is removed and a p-type region 40 formed with an aluminum region containing mostly aluminum is formed in the surface of an n-type drift layer 4 immediately below each gate electrode 28. The p-type region 40 is in contact with the gate electrode 28. The area of each p-type region 40 formed with an aluminum region is larger than the area of the lower surface of the corresponding gate electrode 28, and a shadow of each gate electrode 28 case from the element surface always falls within the corresponding p-type region 40.

Where the SiC junction field-effect transistor of this embodiment is a transistor of a normally ON type, a negative bias is applied to the gate electrodes 28 in an OFF state, and a depletion layer is extended to the channel region, thereby cutting off the current. In the case of the normally ON type transistor, while a bias is not applied to the gate electrodes 28, the transistor is in ON state.

In a case of a transistor of a normally OFF type, a spontaneous extension of a depletion layer at the time of thermal equilibrium with the channel region cuts off the current, even though a bias is not applied to the gate electrodes 28.

In an ON state, a positive bias is applied to the gate electrodes 28 so as to reduce the width of the depletion layer. However, if the bias to be applied is 2.5 V or higher, holes are injected to the channel regions through the p-type regions 40.

Each aluminum region 14 has a larger area than the area of the bottom face of each source electrode 26, and a shadow of each source electrode 26 cast from the element surface always falls within the corresponding aluminum region 14, so as to prevent a dynamic punchthrough effect. Furthermore, the area of each aluminum region 14 is larger than the contact area between each source electrode 26 and the corresponding p-type contact region 8 and the corresponding source region 18, and shadows of each source electrode 26 and the corresponding source region 18 cast from the element surface always fall within the corresponding aluminum region 14.

In a modification of this embodiment, the aluminum regions 14 may be connected directly to the source electrodes 26, as shown in FIG. 36.

Like the fifth embodiment, this embodiment and the modification can most effectively prevent a decrease in breakdown voltage, and restrict dynamic punchthrough.

### Sixteenth Embodiment

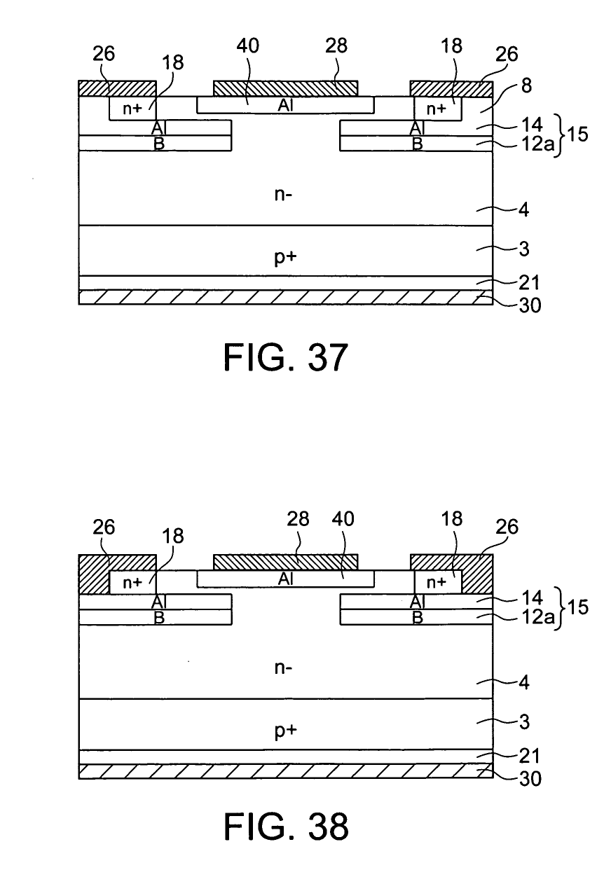

Referring now to FIG. 37, a SiC static induction thyristor according to a sixteenth embodiment of the present invention is described. The SiC static induction thyristor of this embodiment differs from the SiC junction field-effect transistor of the fifteenth embodiment in that the n-type SiC substrate 2 is replaced with a p-type SiC substrate 3 and the n-type drain contact region 20 is replaced with a p-type drain contact region 21. The p-type drain contact region 21 is formed by implanting p-type impurity ions (such as aluminum ions). The thickness and concentration of the drift layer 4 are set within ±50% (more preferably ±20%) of the optimum conditions described in First Embodiment.

In a modification of this embodiment, the aluminum regions 14 may be connected directly to the source electrodes 26, as shown in FIG. 38.

Like the fifteenth embodiment, this embodiment and the modification can most effectively prevent a decrease in breakdown voltage, and restrict dynamic punchthrough.

### Seventeenth Embodiment

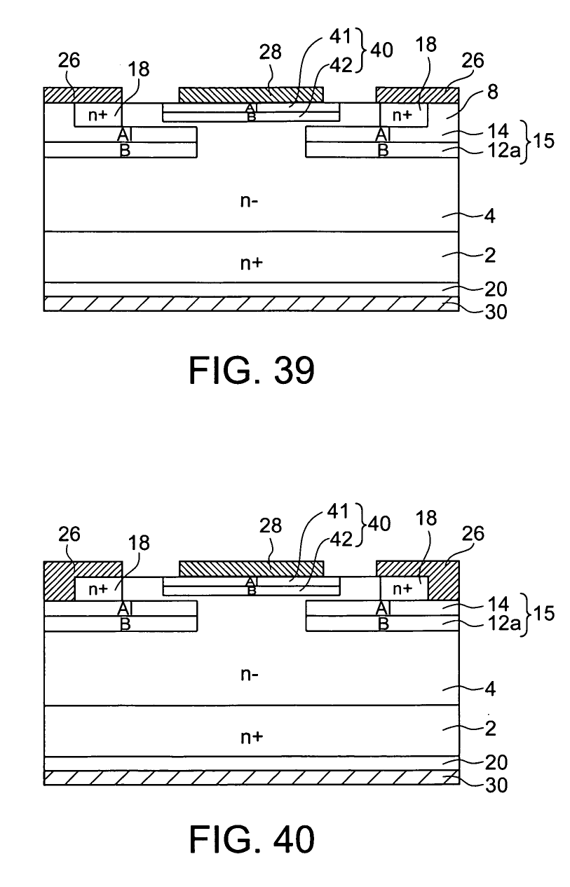

Referring now to FIG. 39, a SiC junction field-effect transistor (a static induction transistor) according to a seventeenth embodiment of the present invention is described. The SiC junction field-effect transistor of this embodiment is the same as the SiC junction field-effect transistor of the fifteenth embodiment illustrated in FIG. 35, except that the p-type regions 40 each formed with an aluminum layer are replaced with p-type regions 40 each formed with an aluminum region 41 and a boron region 42. In this structure, at least the bottom surface of each aluminum region 41 containing mostly aluminum is covered with the corresponding region 42 containing boron. Accordingly, the concentration profile of aluminum in the depth direction is designed to be equal to or shallower than the profile of boron in the depth direction.

In a modification of this embodiment, the aluminum regions 14 may be connected directly to the source electrodes 26, as shown in FIG. 40.

Like the fifteenth embodiment, this embodiment and the modification can most effectively prevent a decrease in breakdown voltage, and restrict dynamic punchthrough.

### Eighteenth Embodiment

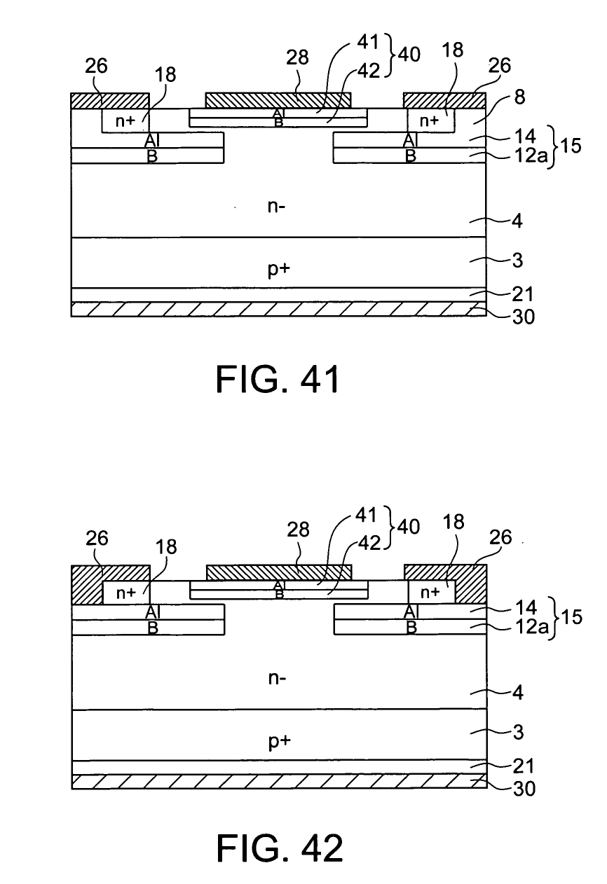

Referring now to FIG. 41, a SiC static induction thyristor according to an eighteenth embodiment of the present invention is described. The SiC static induction thyristor of this embodiment differs from the SiC junction field-effect transistor of the seventeenth embodiment in that the n-type SiC substrate 2 is replaced with a p-type SiC substrate 3 and the n-type drain contact region 20 is replaced with a p-type drain contact region 21. The p-type drain contact region 21 is formed by implanting p-type impurity ions (such as aluminum ions). The thickness and concentration of the drift layer 4 are set within ±50% (more preferably ±20%) of the optimum conditions described in First Embodiment.

In a modification of this embodiment, the aluminum regions 14 may be connected directly to the source electrodes 26, as shown in FIG. 42.

Like the seventeenth embodiment, this embodiment and the modification can most effectively prevent a decrease in breakdown voltage, and restrict dynamic punchthrough.

### Nineteenth Embodiment

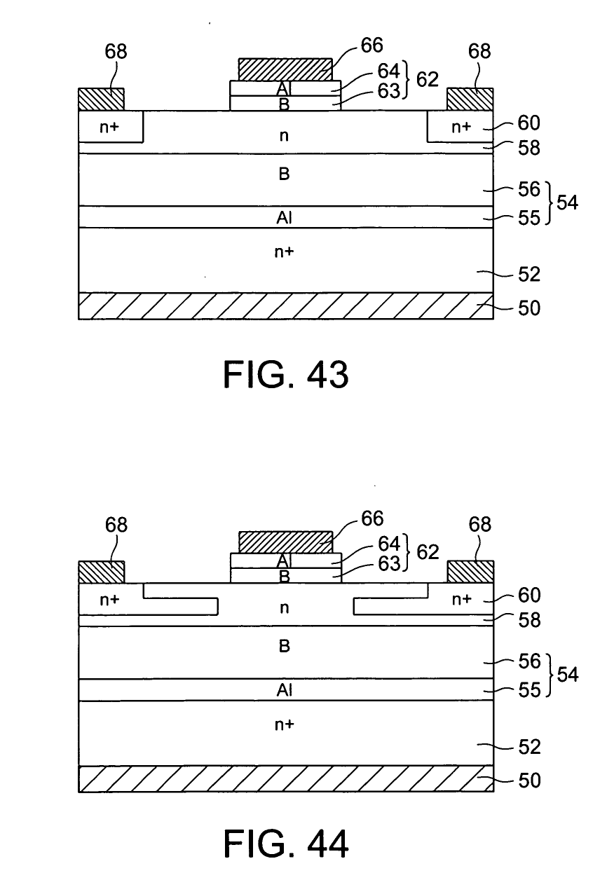

Referring now to FIG. 43, a SiC gate turn-off thyristor according to a nineteenth embodiment of the present invention is described. The SiC gate turn-off thyristor of this embodiment has a p-type region 54 that is formed with an aluminum region 55 and a boron region 56, and forms a main junction with an n-type drift layer 58. The aluminum region 55 and the boron region 56 are SiC semiconductor layers. In a p-type region 62 joined to an anode electrode 66, at least the cathode side of an aluminum region 64 containing mostly aluminum is covered with a region 63 containing boron. Also, at least the anode side of the p-type region 54 formed on the surface of an n-type region 52 joined to a cathode electrode 50 is covered with the region 56 containing boron. The n-type drift layer 58 has n+ regions 60 connected to gate electrodes 68.

In this embodiment, so as to prevent dynamic punchthrough, the film area of the aluminum region 55 is larger than the area of the lower face of the anode electrode 66.

Also in this embodiment, the p-type regions on the anode side and the cathode side of the gate turn-off thyristor contain aluminum and boron elements. However, both sides are not necessarily p-type regions containing the two kinds of elements, and regions that do not have an intense electric field due to the device configuration may be formed with only one kind of elements (aluminum or boron).

While the gate turn-off thyristor of this embodiment illustrated in FIG. 43 is a typical gate turn-off thyristor, the areas of the n-type regions 60 connected to the gate electrodes 68 may be made larger, as shown in FIG. 44. Thus, electron discharge is made easier, and the discharge resistance can be lowered.

### Twentieth Embodiment

A method of forming a boron region through ion implantation according to a twentieth embodiment of the present invention is now described.

In a case where the transistor of the structure illustrated in FIG. 19 is to be formed, for example, boron diffusion in the vertical direction (downward) at the time of the formation of the boron regions 12a is effective for maintaining breakdown voltage. However, upward (transverse channel direction) diffusion or transverse direction (vertical channel direction) diffusion narrows the channel region, resulting in an increase in resistance.

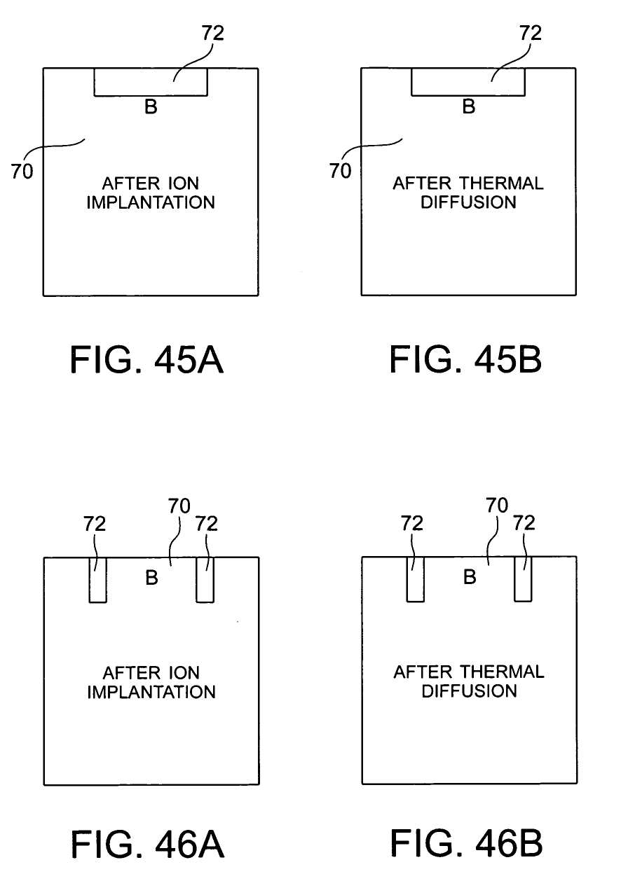

Therefore, carbon is also implanted in the region in which boron diffusion due to activation anneal is to be restrained. Thus, boron thermal diffusion can be restrained. As shown in FIG. 45A, for example, carbon is also implanted selectively in the upper portion of a boron implanting region 70, so as to form a carbon implanting region 72. By doing so, upward thermal diffusion of boron can be restrained, as shown in FIG. 45B, even though activation anneal is performed. Also, carbon is also implanted selectively in side portions of the boron implanting region 70, so as to form carbon implanting regions 72, as shown in FIG. 46A. By doing so, transverse thermal diffusion of boron can be restrained, as shown in FIG. 46B, even though activation anneal is performed.

Also, SiC naturally contains carbon in itself. However, in a region in which carbon is also implanted through analysis such as SIMS (Secondary Ion Mass Spectroscopy), the carbon concentration is high.

As described so far, any of the above described embodiments of the present invention can most effectively prevent a decrease in breakdown voltage.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A field-effect transistor comprising:
a drain region made of SiC;
a drift layer which is formed on the drain region and is made of n-type SiC;
a source region which is formed on a surface of the drift layer and is made of n-type SiC;
a channel region which is formed on a surface of the drift layer located on a side of the source region and is made of SiC;
an insulating gate formed on the channel region; and
a p-type base region interposed between a bottom portion of the source region and the drift layer, and containing two kinds of p-type impurities.

2. The field-effect transistor as claimed in claim 1, further comprising a p-type contact region which is to be electrically connected to the base region and is formed in the source region.

3. The field-effect transistor as claimed in claim 1, wherein:
the two kinds of p-type impurities in the base region are boron and aluminum; and
a lower plane of the region containing boron of the p-type base region is located at the same position as or at a deeper position than a lower plane of the region containing aluminum of the p-type base region.

4. The field-effect transistor as claimed in claim 3, wherein at least one of a side portion and an upper portion of the region containing boron of the p-type base region has a region with a higher carbon concentration than the region containing boron.

5. The field-effect transistor as claimed in claim 3, wherein:
a source electrode connecting to the source region is formed on the source region;
the lower surface of the source electrode has a smaller area than the film area of the region containing aluminum of the p-type base region; and
when the p-type base region is seen from the source electrode, the source electrode is located within the region containing aluminum of the p-type base region.

6. The field-effect transistor as claimed in claim 1, wherein the channel region is of a p-type.

7. The field-effect transistor as claimed in claim 1, wherein the channel region is of an n-type.

8. The field-effect transistor as claimed in claim 6, wherein the channel region is an epitaxial layer.

9. The field-effect transistor as claimed in claim 7, further comprising a p-type layer which is provided between the channel region and the p-type base region, and contains boron.

10. The field-effect transistor as claimed in claim 1, wherein the drain region is of an n-type.

11. The field-effect transistor as claimed in claim 1, wherein the drain region is of a p-type.

12. A field-effect transistor comprising:
a drain region made of SiC;
a drift layer which is formed on the drain region and is made of n-type SiC;
a channel region which is formed on the drift layer and is made of SiC;
a gate region which is formed on the channel region and is made of p-type SiC;
a gate electrode connected to the gate region;
a source region being adjacent to the channel region; and
a p-type base region interposed between a bottom portion of the source region and the drift region, and containing two kinds of p-type impurities.

13. The field-effect transistor as claimed in claim 12, further comprising a p-type contact region which is to be electrically connected to the base region and is formed in the source region.

14. The field-effect transistor as claimed in claim 12, wherein:
the gate region is made of SiC containing two kinds of p-type impurities;
the two kinds of p-type impurities are boron and aluminum; and
a lower plane of the region containing boron of the gate region is located at the same position as or at a deeper position than a lower plane of the region containing aluminum of the gate region.

15. The field-effect transistor as claimed in claim 14, wherein at least one of a side portion and an upper portion of the region containing boron of the gate region has a region with a higher carbon concentration than the region containing boron.

16. The field-effect transistor as claimed in claim 12, wherein:
the two kinds of p-type impurities in the base region are boron and aluminum; and
a lower plane of the region containing boron of the p-type base region is located at the same position as or at a deeper position than a lower plane of the region containing aluminum of the p-type base region.

17. The field-effect transistor as claimed in claim 16, wherein at least one of a side portion and an upper portion of the region containing boron of the p-type base region has a region with a higher carbon concentration than the region containing boron.

18. The field-effect transistor as claimed in claim 16, wherein:
a source electrode connecting to the source region is formed on the source region;
the lower surface of the source electrode has a smaller area than the film area of the region containing aluminum of the p-type base region; and
when the p-type base region is seen from the source electrode, the source electrode is located within the region containing aluminum of the p-type base region.

19. The field-effect transistor as claimed in claim 12, wherein the channel region is of an n-type.

20. The field-effect transistor as claimed in claim 19, further comprising a p-type layer which is provided between the channel region and the p-type base region, and contains boron.

21. The field-effect transistor as claimed in claim 12, wherein the drain region is of an n-type.

22. The field-effect transistor as claimed in claim 12, wherein the drain region is of a p-type.

23. A thyristor comprising:
a cathode electrode;
an n-type layer which is made of SiC and is formed on the cathode electrode;
a first layer which is made of SiC, is formed on the n-type layer, and contains aluminum;
a second layer which is made of SiC, is formed on the first layer containing aluminum, and contains boron;
an n-type drift layer which is made of SiC and is formed on the second layer containing boron;
a p-type region which includes a third layer that is formed on the n-type drift layer and contains boron, and a fourth layer that is formed on the third layer containing boron and contains aluminum;
an anode electrode formed on the p-type region, the anode electrode having a lower face which has a smaller area than the film area of the first and fourth layers containing aluminum, and being located within the first and fourth layers containing aluminum, when the first and fourth layers containing aluminum are seen from the anode electrode;
an n-type region which is formed on the n-type drift layer; and
a gate electrode which is connected to the n-type region.
